(19) United States
(12) Patent Application Publication
(10) Pub. No.: US 2024/0120324 A1
(43) Pub. Date: Apr. 11, 2024

(54) APPARATUS FOR FABRICATING DISPLAY PANEL AND FABRICATING METHOD THEREOF

(71) Applicant: Samsung Display Co., LTD., Yongin-si (KR)

(72) Inventors: Tae Hee LEE, Yongin-si (KR); Kyung Ho KIM, Yongin-si (KR); Young Seok SEO, Yongin-si (KR); Joo Woan CHO, Yongin-si (KR); Byeong Hwa CHO, Yongin-si (KR)

(21) Appl. No.: 18/462,004

(22) Filed: Sep. 6, 2023

(30) Foreign Application Priority Data
Oct. 6, 2022 (KR) 10-2022-0127976
Nov. 23, 2022 (KR) 10-2022-0157889

(51) Int. Cl. H01L 25/075

(52) U.S. Cl. CPC H01L 25/0753

(57) ABSTRACT

An apparatus for fabricating a display panel, including a film fixing module configured to fix a stretched film on which a plurality of light emitting elements are arranged, a film pressurizing module configured to pressurize the stretched film, a first thickness detection module configured to detect, at each pressurization step, a modulus of elasticity and a change in thickness of the stretched film that is pressurized and stretched by the film pressurizing module, a second thickness detection module configured to detect, at each pressurization step, a change in thickness of an adhesive applied in a front direction of the stretched film, an image detection module configured to photograph the plurality of light emitting elements arranged on the stretched film for each pressurization step and to detect a change in arrangement information of the light emitting elements, and a main processor configured to database feature change information.

### CROSS-REFERENCE TO RELATED APPLICATIONS

This application claims priority to and the benefit of Korean Patent Application No. 10-2022-0127976 filed on Oct. 6, 2022, and Korean Patent Application No. 10-2022-0157889 filed on Nov. 23, 2022, in the Korean Intellectual Property Office, the entire contents of all of which are incorporated by reference herein.

### BACKGROUND

### 1. Field

The present disclosure relates to an apparatus for fabricating a display panel and a fabricating method thereof.

### 2. Description of the Related Art

The importance of display devices has steadily increased with the development of multimedia technology. In response thereto, various types of display devices such as an organic light emitting diode (OLED) display, a liquid crystal display (LCD) and the like have been used.

A display device is a device for displaying an image, and includes a display panel, such as a light emitting display panel or a liquid crystal display panel. Among them, the light emitting display panel may include a light emitting diode (LED), and the light emitting diode includes an organic light emitting diode (OLED) using an organic material as a fluorescent material or an inorganic light emitting diode using an inorganic material as a fluorescent material.

In fabricating a display panel using an inorganic light emitting diode as a light emitting element, fabricating apparatuses for accurately arranging and transferring light emitting diodes such as micro LEDs onto a substrate of the display panel are required.

### SUMMARY

Aspects and features of embodiments of the present disclosure provide an apparatus for fabricating a display panel and a fabricating method thereof capable of pre-standardizing stretching characteristics of a stretched film on which light emitting diodes are arranged to correspond to structural features of pixels of each display panel.

Aspects and features of embodiments of the present disclosure also provide an apparatus for fabricating a display panel and a fabricating method thereof capable of comparing and analyzing stretching characteristics, such as pressing force of a stretched film, modulus of elasticity, density change of light emitting diodes, change in adhesive thickness, and transfer rate, against structural features of pixels for each display panel.

However, aspects and features of embodiments of the present disclosure are not restricted to those set forth herein. The above and other aspects and features of embodiments of the present disclosure will become more apparent to one of ordinary skill in the art to which the present disclosure pertains by referencing the detailed description of the present disclosure given below.

According to one or more embodiments of the present disclosure, an apparatus for fabricating a display panel, including a film fixing module configured to fix a stretched film on which a plurality of light emitting elements are arranged, a film pressurizing module configured to pressurize the stretched film, a first thickness detection module configured to detect, at each pressurization step, a modulus of elasticity and a change in thickness of the stretched film that is pressurized and stretched by the film pressurizing module, a second thickness detection module configured to detect, at each pressurization step, a change in thickness of an adhesive applied in a front direction of the stretched film, an image detection module configured to photograph the plurality of light emitting elements arranged on the stretched film for each pressurization step and to detect a change in arrangement information of the light emitting elements, and a main processor configured to database feature change information of at least one of the thickness of the stretched film, the modulus of elasticity, the thickness of the adhesive, or the arrangement information of the light emitting elements according to a change in pressing force for each pressurization step.

In one or more embodiments, the film pressurizing module pressurizes one surface of the stretched film by gradually increasing the pressing force for each pressurization step in n steps, where n is a positive integer.

In one or more embodiments, the first thickness detection module is located in a stretching direction in which the stretched film is stretched or in one lateral direction in which the stretched film is stretched to detect, at each pressurization step, a change in the thickness of the stretched film and a modulus of elasticity that varies depending on the change in thickness of the stretched film, and wherein the first thickness detection module is configured to transmit elastic modulus detection data and first thickness detection data according to the change in the thickness of the stretched film to the main processor.

In one or more embodiments, the second thickness detection module is configured to detect a light quantity detection signal corresponding to a change in the adhesive thickness of the stretched film by using at least one light receiving element, a light emitting element, and a sensor under control of a microprocessor, and convert the light quantity detection signal to a digital data signal to transmit second thickness detection data corresponding to the change in the adhesive thickness in the front direction of the stretched film to the main processor.

In one or more embodiments, the image detection module is configured to analyze arrangement images of the light emitting elements for each pressurization step of the stretched film to detect damage rate data, transfer rate data and density change information of the light emitting elements for each pressurization step of the stretched film, and transmit the damage rate data, the transfer rate data, and the density change information of the light emitting elements to the main processor.

In one or more embodiments, the main processor is configured to receive pressing force magnitude information for each pressurization step from the film pressurizing module, and based on the pressing force magnitude information for each step of the film pressurizing module, sort and database specifications including at least one feature selected from the group of type, model name, or area of the stretched film, the first thickness detection data, the elastic modulus detection data, the second thickness detection data, the damage rate data of the light emitting elements, the transfer rate data, and the density change information of the light emitting elements. In one or more embodiments, the main processor is configured to match and

compare layout shape data including a pixel size, pixel shape, and pixel arrangement structure of a display substrate for each display panel set in advance with the arrangement images of the light emitting elements, and to generate and output a simulation result image in which the light emitting elements of the stretched film are transferred to the pixel shapes of the display substrate.

In one or more embodiments, the main processor is configured to match the transfer rate data and the density change information of the light emitting elements for each pressurization step compared to layout shape data including a pixel size, pixel shape, and pixel arrangement structure of a display substrate for each display panel set in advance, and to output, as a simulation result, a layout drawing obtained by matching the layout shape data of the display substrate with the transfer rate data and the density change information of the light emitting elements.

In one or more embodiments, the main processor includes an elastic modulus detection unit configured to extract a thickness change value and an elastic modulus value according to the change in thickness of the stretched film that is pressurized and stretched for each step by the film pressurizing module through the first thickness detection data from the first thickness detection module, an image analysis unit configured to analyze the arrangement images of the light emitting elements inputted from the image detection module to detect each of the damage rate data and the transfer rate data of the light emitting elements for each pressurization step of the stretched film, a density detection unit configured to analyze the arrangement images of the light emitting elements to detect the density change information of the light emitting elements for each pressurization step, a data analysis processing unit configured to sort and database specifications including type, model name, and area information of the stretched film, the first thickness detection data, the elastic modulus detection data, and the second thickness detection data based on pressing force magnitude information for each step of the film pressurizing module, and a result output unit configured to output at least one of the databased specification to a separate server or monitor.

In one or more embodiments, based on the pressing force magnitude information for each step of the film pressurizing module, the data analysis processing unit is configured to sort and database specifications including at least one feature selected from the group consisting of type, model name, or area of the stretched film, the first thickness detection data, the elastic modulus detection data, the second thickness detection data, the damage rate data of the light emitting elements, the transfer rate data, and the density change information of the light emitting elements.

In one or more embodiments, the main processor further includes a simulation processing unit configured to match and compare layout shape data including a pixel size, pixel shape, and pixel arrangement structure of a display substrate for each display panel set in advance with the arrangement images of the light emitting elements, and generate a simulation result image in which the light emitting elements of the stretched film are transferred to the pixel shapes of the display substrate.

In one or more embodiments, the main processor further includes a simulation processing unit configured to match the transfer rate data and the density change information of the light emitting elements for each pressurization step compared to layout shape data including a pixel size, pixel shape, and pixel arrangement structure of a display substrate for each display panel set in advance, and output, as a simulation result, a layout drawing obtained by matching the layout shape data of the display substrate with the transfer rate data and the density change information of the light emitting elements.

According to one or more embodiments of the present disclosure, a fabricating method of a display panel, including fixing a stretched film on which a plurality of light emitting elements are arranged to a film fixing module, pressurizing, by a film pressurizing module, the stretched film, detecting, by a first thickness detection module, at each pressurization step, a modulus of elasticity and a change in thickness of the stretched film that is pressurized and stretched by the film pressurizing module, detecting, by a second thickness detection module, at each pressurization step, a change in thickness of an adhesive applied in a front direction of the stretched film, photographing, by an image detection module, the plurality of light emitting elements arranged on the stretched film for each pressurization step and detecting a change in arrangement information of the light emitting elements, and databasing, by a main processor, feature change information of at least one of the thickness of the stretched film, the modulus of elasticity, the thickness of the adhesive, or the arrangement information of the light emitting elements according to a change in pressing force for each pressurization step.

In one or more embodiments, the pressurizing of the stretched film includes pressurizing, by the film pressurizing module, one surface of the stretched film by gradually increasing the pressing force for each pressurization step in n steps, where n is a positive integer.

In one or more embodiments, the detecting of the modulus of elasticity of the stretched film at each pressurization step includes detecting, at each pressurization step, a change in the thickness of the stretched film and a modulus of elasticity that varies depending on the change in the thickness, and transmitting elastic modulus detection data and first thickness detection data according to the change in the thickness of the stretched film to the main processor.

In one or more embodiments, the detecting of a change in the adhesive thickness includes: detecting a light quantity detection signal corresponding to the change in the adhesive thickness of the stretched film by using at least one light receiving element, a light emitting element, and a sensor under control of a microprocessor, and converting the light quantity detection signal into a digital data signal to transmit second thickness detection data corresponding to the change in the adhesive thickness in the front direction of the stretched film to the main processor.

In one or more embodiments, the detecting of the change in arrangement information of the light emitting elements includes analyzing arrangement images of the light emitting elements for each pressurization step of the stretched film to detect damage rate data, transfer rate data and density change information of the light emitting elements for each pressurization step of the stretched film, and transmitting the damage rate data, the transfer rate data, and the density change information of the light emitting elements to the main processor.

In one or more embodiments, the databasing of the feature change information of the light emitting elements includes receiving pressing force magnitude information for each pressurization step from the film pressurizing module, and based on the pressing force magnitude information for each step of the film pressurizing module, sorting specifications including at least one feature selected from the group consisting of type, model name, or area of the stretched film, first thickness detection data, elastic modulus detection data, the second thickness detection data, damage rate data of the light emitting elements, transfer rate data, and density change information of the light emitting elements.

In one or more embodiments, the databasing of the feature change information of the light emitting elements further includes matching and comparing layout shape data including a pixel size, pixel shape, and pixel arrangement structure of a display substrate for each display panel set in advance with arrangement images of the light emitting elements, and generating and outputting a simulation result image in which the light emitting elements of the stretched film are transferred to the pixel shapes of the display substrate.

In one or more embodiments, the databasing of the feature change information of the light emitting elements further includes matching the transfer rate data and the density change information of the light emitting elements for each pressurization step compared to layout shape data including a pixel size, pixel shape, and pixel arrangement structure of a display substrate for each display panel set in advance, and outputting, as a simulation result, a layout drawing obtained by matching the layout shape data of the display substrate with the transfer rate data and the density change information of the light emitting elements.

In the apparatus for fabricating the display device according to embodiments, the stretching characteristics of the stretched film on which the light emitting diodes are arranged compared to the structural features of the pixels for each display panel may be standardized to increase the efficiency of transfer and adhesion of the light emitting diodes and improve the reliability of the transfer process.

In addition, by estimating transfer and adhesion results of the light emitting diodes and deriving simulation results, it is possible to minimize the transfer defect rate of the light emitting diodes and increase the fabricating efficiency of the display panel.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view of a display device according to one or more embodiments of the present disclosure;

FIG. 2 is a plan view schematically illustrating an emission area of each pixel according to one or more embodiments;

FIG. 3 is a plan view schematically illustrating an emission area of each pixel according to one or more embodiments;

FIG. 4 is an equivalent circuit diagram of each pixel according to one or more embodiments;

FIG. 5 is an equivalent circuit diagram of each of pixels according to one or more embodiments;

FIG. 6 is a cross-sectional view schematically illustrating a cross section taken along the line A-A′ of FIG. 2 according to one or more embodiments;

FIG. 7 is an enlarged view schematically illustrating the first emission area of FIG. 6;

FIG. 8 is a cross-sectional view specifically illustrating the light emitting element of FIG. 7;

FIG. 9 is a cross-sectional view schematically illustrating a cross section taken along the line A-A′ of FIG. 2 according to one or more embodiments;

FIG. 10 is a cross-sectional view schematically illustrating a cross section taken along the line A-A′ of FIG. 2 according to one or more embodiments;

FIG. 11 is a perspective view schematically illustrating an apparatus for fabricating a display panel according to one or more embodiments;

FIG. 12 is a cross-sectional view showing cross-sectional structures of a film fixing module, a film pressurizing module, a main processor, and the like shown in FIG. 11;

FIG. 13 is a cross-sectional view showing a process of pressurizing and stretching a stretched film by the film pressurizing module shown in FIG. 12;

FIG. 14 is a block diagram showing the main processor of FIGS. 11 and 12 in detail;

FIG. 15 is a view showing an arrangement image of light emitting elements detected through an image detection module in a first step of pressurizing the stretched film by the film pressurizing module shown in FIG. 11;

FIG. 16 is a cross-sectional view showing a cross section along the line I-I′ of FIG. 15;

FIG. 17 is a view showing an arrangement image of light emitting elements detected through an image detection module in a second step of pressurizing the stretched film by the film pressurizing module shown in FIG. 11;

FIG. 18 is a cross-sectional view showing a cross section along the line I-I′ of FIG. 17;

FIG. 19 is a view showing an arrangement image of light emitting elements detected through an image detection module in a third step of pressurizing the stretched film by the film pressurizing module shown in FIG. 11;

FIG. 20 is a cross-sectional view showing a cross section along the line I-I′ of FIG. 19;

FIG. 21 is a layout diagram showing a simulation result image of a main processor according to one or more embodiments;

FIG. 22 is a layout diagram showing a simulation result image of a main processor according to one or more embodiments;

FIG. 23 is a diagram illustrating a vehicle instrument panel and a center fascia including a display device according to one or more embodiments;

FIG. 24 is a diagram illustrating a glasses type virtual reality device including a display device according to one or more embodiments;

FIG. 25 is a diagram illustrating a watch type smart device including a display device according to one or more embodiments; and

FIG. 26 is a diagram illustrating a transparent display device including a display device according to one or more embodiments.

### DETAILED DESCRIPTION

Hereinafter, embodiments will be described in detail with reference to the accompanying drawings.

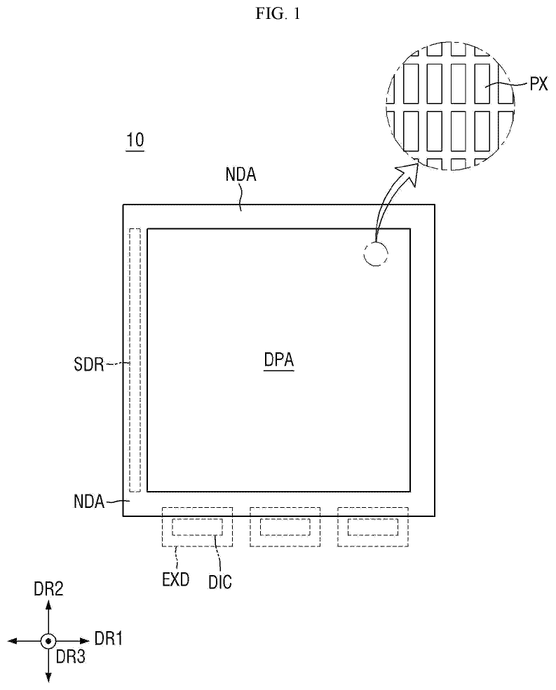

FIG. 1 is a plan view of a display device according to one or more embodiments of the present disclosure.

Referring to FIG. 1, a display device 10 according to one or more embodiments may be applied to a smartphone, a mobile phone, a tablet PC, a personal digital assistant (PDA), a portable multimedia player (PMP), a television, a game machine, a wristwatch-type electronic device, a head-mounted display, a monitor of a personal computer, a laptop computer, a car navigation system, a car's dashboard, a digital camera, a camcorder, an external billboard, an electronic billboard, a medical device, an inspection device, various household appliances such as a refrigerator and a washing machine, and/or an Internet-of-Things (IoT) device. Herein, a television (TV) is described as an example of a display device, and the TV may have a high resolution or an ultra-high resolution such as HD, UHD, 4K and 8K.

In addition, the display device 10 according to one or more embodiments may be classified into various types according to a display method. Examples of the display device may include an organic light emitting display (OLED) device, an inorganic light emitting display (inorganic EL) device, a quantum dot light emitting display (QED) device, a micro-LED display device, a nano-LED display device, a plasma display device (PDP), a field emission display (FED) device, a cathode ray tube (CRT) display device, a liquid crystal display (LCD) device, an electrophoretic display (EPD) device, and the like. Hereinafter, the micro-LED display device will be described as an example of the display device 10, and the micro-LED display device applied to the embodiment will be simply referred to as a display device unless special distinction is required. However, one or more embodiments of the present disclosure are not limited to the micro-LED display device, and other display devices mentioned above or known in the art may be applied within the same scope of technical spirit of the present disclosure.

In addition, in the drawings, a first direction DR1 indicates a horizontal direction of the display device 10, a second direction DR2 indicates a vertical direction of the display device 10, and a third direction DR3 indicates a thickness direction of the display device 10. In this case, “left”, “right”, “upper” and “lower” indicate directions when the display device 10 is viewed from above. For example, “right side” indicates one side of the first direction DR1, “left side” indicates the other side of the first direction DR1, “upper side” indicates one side of the second direction DR2, and “lower side” indicates the other side of the second direction DR2. Further, “above” indicates one side in the third direction DR3, and “below” indicates the other side in the third direction DR3.

The display device 10 according to one or more embodiments may have a circular shape, an elliptical shape, or a square shape in a plan view, for example, a regular tetragonal shape. In addition, when the display device 10 is a television, it may have a rectangular shape with a long side positioned in the horizontal direction. However, the present disclosure is not limited thereto, and the long side of the display device 1 may extend in a vertical direction. Alternatively, the display device 1 may be installed to be rotatable such that its long side is variably positioned to extend in the horizontal or vertical direction.

The display device 10 may include the display area DPA and a non-display area NDA. The display area DPA may be an active area in which an image is displayed. The display area DPA may have a square shape in a plan view similar to the overall shape of the display device 10, but is not limited thereto and may have a circular shape or an elliptical shape.

The display area DPA may include a plurality of pixels PX. The plurality of pixels PX may be arranged in a matrix. For example, the plurality of pixels PX may be arranged along rows and columns of a matrix. The shape of each pixel PX may be rectangular or square in a plan view. However, without being limited thereto, each pixel PX may have a rhombic shape of which each side is inclined with respect to one side direction of the display device 10. The pixels PX may include multiple color pixels PX. For example, the pixels PX may include, a first color pixel PX of red, a second color pixel PX of green, and a third color pixel PX of blue. The present disclosure is not limited thereto, and the plurality of pixels PX may further include a fourth color pixel PX of white. The color pixels PX may be alternately arranged in a stripe type or a PENTILE® structure, or the like. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea.

The non-display area NDA may be disposed around the display area DPA along an edge or periphery of the display area DPA. The non-display area NDA may completely or partially surround the display area DPA. The display area DPA may have various shapes such as a circle shape or a square shape. The non-display area NDA may be formed to surround the periphery of the display area DPA in response to the shape of the display area DPA. The non-display area NDA may be a bezel portion of the display device 10.

In the non-display area NDA, a driving circuit or a driving element for driving the display area DPA may be disposed. In one or more embodiments, in an area of the non-display area NDA that is disposed adjacent to a first side (lower side in FIG. 1) of the display device 10, a pad portion may be provided on a display substrate of the display device 10, and an external device EXD may be mounted on pad electrodes of the pad portion. Examples of the external device EXD may include a connection film, a printed circuit board, a driver integrated circuit (DIC), a connector, a wire connection film and the like. A scan driver SDR directly formed on the display substrate of the display device 10 may be provided in an area of the non-display area NDA that is disposed adjacent to a second side (left side in FIG. 1) of the display device 10.

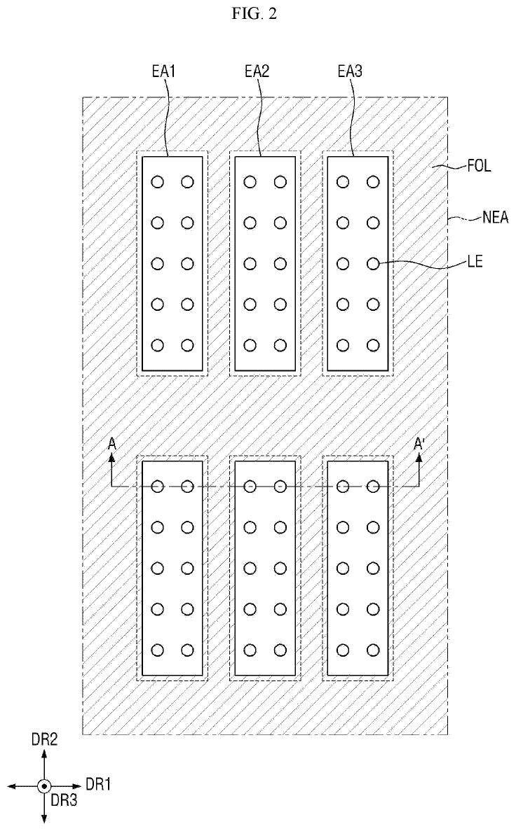

FIG. 2 is a plan view schematically illustrating an emission area of each pixel according to one or more embodiments.

Referring to FIG. 2, the plurality of pixels PX may be arranged in a stripe type in a matrix direction, and the plurality of pixels PX may be divided into a first color pixel PX of red, a second color pixel PX of green, and a third color pixel PX of blue. Further, the plurality of pixels PX may be divided to further include a fourth color pixel PX of white.

The pixel electrode of the first color pixel PX may be positioned in a first emission area EA1 of the first color pixel PX, but at least a part thereof may extend to a non-emission area NEA. The pixel electrode of the second color pixel PX may be positioned in a second emission area EA2 of the second color pixel PX, but at least a part thereof may extend to the non-emission area NEA. The pixel electrode of the third color pixel PX may be positioned in a third emission area EA3 of the third color pixel PX, but at least a part thereof may extend to the non-emission area NEA. A pixel electrode of each pixel PX may penetrate at least one layer of the insulating layers to be connected to any one switching element included in each pixel circuit.

A plurality of light emitting elements LE are disposed on the pixel electrode of the first emission area EA1, the pixel electrode of the second emission area EA2, and the pixel electrode of the third emission area EA3. That is, the light emitting element LE is disposed in each of the first emission area EA1, the second emission area EA2, and the third emission area EA3. In addition, a first color filter of a red color, a second color filter of a green color, and a third color filter of a blue color may be disposed on the first emission area EA1, the second emission area EA2, and the third emission area EA3 in which the plurality of light emitting elements LE are disposed, respectively. A first organic layer FOL may be disposed in the non-emission area NEA.

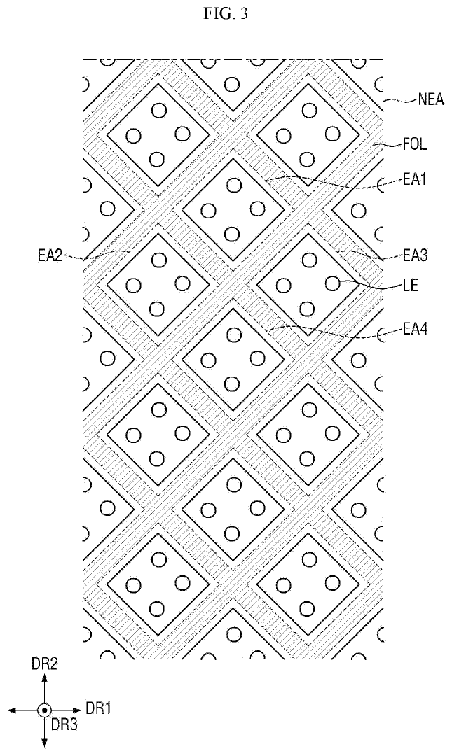

FIG. 3 is a plan view schematically illustrating an emission area of each pixel according to one or more embodiments.

Referring to FIG. 3, the shape of each pixel PX is not limited to a rectangular shape or a square shape in a plan view, and each side of the pixel PX may have a rhombus shape inclined with respect to one side direction of the display device 10 to form a Pentile® matrix structure. Accordingly, in each of the pixels PX of the Pentile® matrix structure, the first emission area EA1 of the first color pixel PX, the second emission area EA2 of the second color pixel PX, the third emission area EA3 of the third color pixel PX, and the fourth emission area EA4 the color pixel PX having the same color as any one of the first to third colors may each be formed in a rhombus shape.

The first to fourth emission areas EA1 to EA4 of each pixel PX may be the same or different in size or planar area. Likewise, the number of light emitting elements LE disposed in each of the first to fourth emission areas EA1 to EA4 may be the same or different.

Specifically, the area of the first emission area EA1, the area of the second emission area EA2, the area of the third emission area EA3, and the area of the fourth emission area EA4 may be substantially the same, but are not limited thereto and may be different from each other. The distance between the first emission area EA1 and the second emission area EA2 adjacent to each other, the distance between the second emission area EA2 and the third emission area EA3 adjacent to each other, the distance between the first emission area EA1 and the third emission area EA3 adjacent to each other, and the distance between the third emission area EA3 and the fourth emission area EA4 adjacent to each other may be substantially the same, but may be different from each other. One or more embodiments of the present disclosure are not limited thereto.

In addition, the first emission area EA1 may emit the first color light, the second emission area EA2 may emit the second color light, and the third emission area EA3 and the fourth emission area EA4 may emit the third color light, but one or more embodiments of the present disclosure are not limited thereto. For example, the first emission area EA1 may emit the second color light, the second emission area EA2 may emit the first color light, and the third and fourth emission areas EA3 and EA4 may emit the third color light. Alternatively, the first emission area EA1 may emit the third color light, the second emission area EA2 may emit the second color light, and the first and fourth emission areas EA3 and EA4 may emit the first color light. Alternatively, at least one emission area of the first to fourth emission areas EA1 to EA4 may emit the fourth color light. The fourth color light may be light of a white or yellow wavelength band. For example, the main peak wavelength of the fourth color light may be positioned at approximately 550 nm to 600 nm, but one or more embodiments of the present disclosure are not limited thereto.

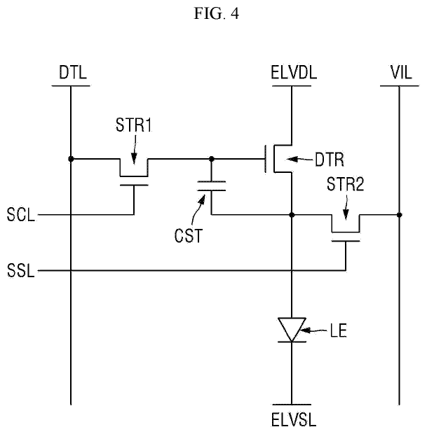

FIG. 4 is an equivalent circuit diagram of each pixel for each of pixels according to one or more embodiments.

Referring to FIG. 4, each pixel PX may include three transistors DTR, STR1 and STR2 for controlling the light emission of the light emitting elements LE and one capacitor CST for storage. A driving transistor DTR adjusts a current flowing from a first power supply line ELVDL to which the first power voltage is supplied to any one light emitting element LE according to a voltage difference between the gate electrode and the source electrode. The gate electrode of the driving transistor DTR may be connected to the first electrode of a first transistor ST1, the source electrode thereof may be connected to the first electrode of any one light emitting element LE, and the drain electrode thereof may be connected to the first power supply line ELVDL to which the first power voltage is applied.

A first transistor STR1 is turned on by the scan signal of a scan line SCL to connect a data line DTL to the gate electrode of the driving transistor DTR. The gate electrode of the first transistor STR1 may be connected to the scan line SL, the first electrode thereof may be connected to the gate electrode of the driving transistor DTR, and the second electrode thereof may be connected to the data line DTL.

A second transistor STR2 is turned on by the sensing signal of a sensing signal line SSL to connect an initialization voltage line VIL to the source electrode of the driving transistor DTR. The gate electrode of the second transistor ST2 may be connected to the sensing signal line SSL, the first electrode thereof may be connected to the initialization voltage line VIL, and the second electrode thereof may be connected to the source electrode of the driving transistor DTR.

In one or more embodiments, the first electrode of each of the first and second transistors STR1 and STR2 may be a source electrode and the second electrode thereof may be a drain electrode, but the present disclosure is not limited thereto, and may be vice versa.

The capacitor CST is formed between the gate electrode and the source electrode of the driving transistor DTR. The storage capacitor CST stores a difference voltage between a gate voltage and a power voltage of the driving transistor DTR.

The driving transistor DTR, the first transistor STR1, and the second transistor STR2 may be formed as thin film transistors (TFTs). Further, in the description of FIG. 4, it is assumed that the driving transistor DTR, the first switching transistor STR1, and the second switching transistor STR2 are N-type metal oxide semiconductor field effect transistors (MOSFETs), but the present disclosure is not limited thereto. That is, the driving transistor DTR, the first switching transistor STR1, and the second switching transistor STR2 may be P-type MOSFETs, or some of the driving transistor DTR, the first switching transistor STR1, and the second switching transistor STR2 may be N-type MOSFETs, while others may be P-type MOSFETs.

The light emitting elements LE may be connected between the source electrode of the driving transistor DTR and a second power line ELVSL.

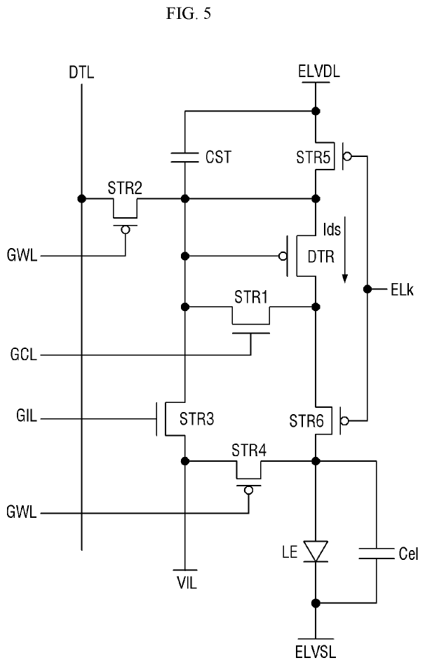

FIG. 5 is an equivalent circuit diagram of each of pixels according to another embodiment.

Referring to FIG. 5, each pixel PX may include a capacitor CST, and a driving transistor DTR and a plurality of switch elements for controlling the light emission of the light emitting elements LE. In this case, the plurality of switch elements may include first to sixth transistors STR1, STR2, STR3, STR4, STR5, and STR6.

The driving transistor DTR includes a gate electrode, a first electrode, and a second electrode. The driving transistor DTR controls a drain-source current Ids (hereinafter, referred to as “driving current”) flowing between the first electrode and the second electrode of the driving transistor DRT according to a data voltage applied to the gate electrode of the driving transistor DRT.

The capacitor CST is formed between the second electrode of the driving transistor DTR and a second power line ELVSL. One electrode of the capacitor CST may be connected to the second electrode of the driving transistor DTR, and the other electrode thereof may be connected to the second power line ELVSL.

When the first electrode of each of the driving transistor DTR and the first to sixth transistors STR1 to STR6 is a source electrode, the second electrode thereof may be a drain electrode. Alternatively, when the first electrode of each of the driving transistor DTR and the first to sixth transistors STR1 to STR6 is a drain electrode, the second electrode thereof may be a source electrode.

The driving transistor DTR, the second transistor STR2, the fourth transistor STR4, the fifth transistor STR5, and the sixth transistor STR6 may be configured as P-type metal oxide semiconductor field effect transistors (MOSFETs), and the first transistor STR1 and the third transistor STR3 may be configured as N-type MOSFETs. Alternatively, the first to sixth transistors STR1, STR2, STR3, STR4, STR5, STR6, and the driving transistor DTR may be formed of a P-type metal oxide semiconductor field effect transistor (MOSFET).

It should be noted that the equivalent circuit diagram of the pixel according to the above-described embodiment of the present disclosure is not limited to those illustrated in FIGS. 4 and 5. The equivalent circuit diagram of the pixel according to one or more embodiments of the present disclosure may be formed in other known circuit structures that those skilled in the art may employ in addition to the embodiments illustrated in FIGS. 4 and 5.

The first transistor STR1 is connected between the gate electrode and the second electrode of the driving transistor DTR. The gate electrode of the first transistor STR1 is connected to a gate control line GCL.

The second transistor STR2 is connected between the data line DTL and the first electrode of the driving transistor DTR. The gate electrode of the second transistor STR2 is connected to a gate write line GWL.

The third transistor STR3 is connected between the gate electrode of the driving transistor DTR and an initialization voltage line VIL. The gate electrode of the third transistor STR3 is connected to a gate initialization line GIL.

The fourth transistor STR4 is connected between a first electrode of the light emitting element LE and the initialization voltage line VIL. The gate electrode of the fourth transistor STR4 is connected to the gate write line GWL.

The fifth transistor STR5 is connected between the first electrode of the driving transistor DTR and the first power line ELVDL. The gate electrode of the fifth transistor STR5 is connected to an emission control line ELk.

The sixth transistor STR6 is connected between the second electrode of the driving transistor DTR and the first electrode of the light emitting element LE. The gate electrode of the sixth transistor STR6 is connected to the emission control line ELk.

The light emitting element LE is connected between the second electrode of the sixth transistor STR6 and a second power line ELVSL.

A capacitor Cel is connected between the first and second electrode of the light emitting element LE.

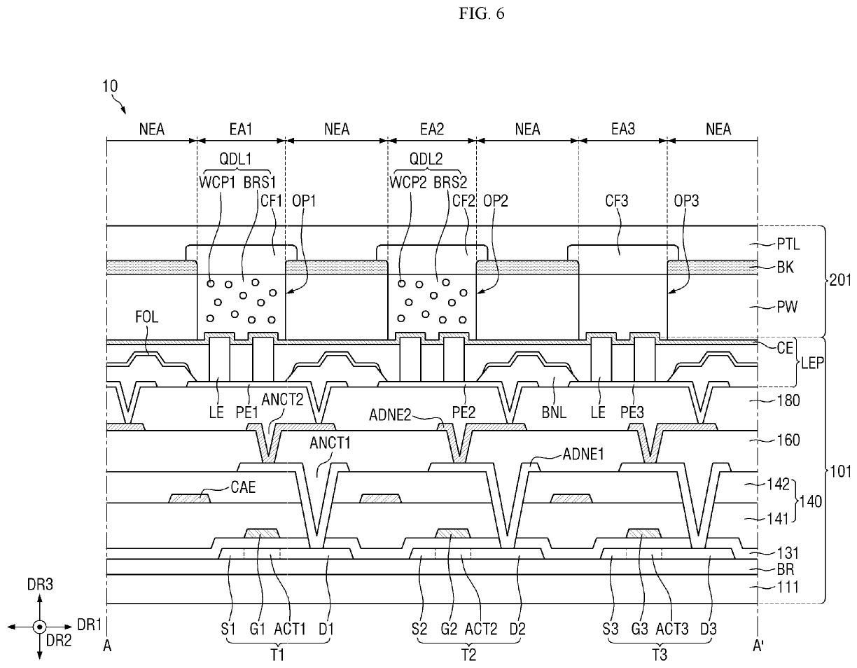

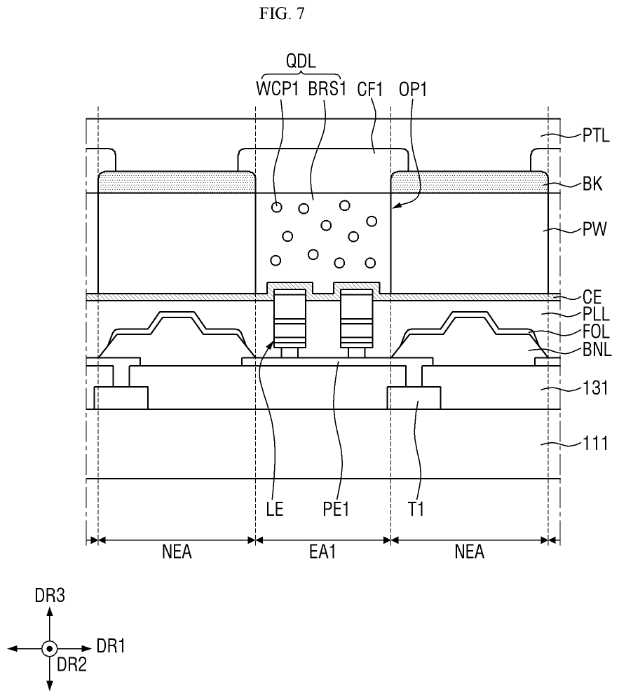

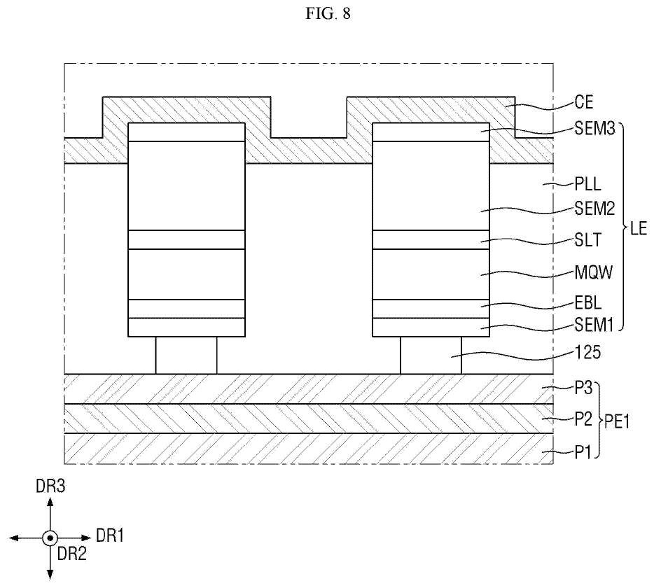

FIG. 6 is a cross-sectional view schematically illustrating a cross section taken along the line A-A′ of FIG. 2 according to one or more embodiments. Further, FIG. 7 is an enlarged view schematically illustrating the first emission area of FIG. 6, and FIG. 8 is a cross-sectional view specifically illustrating the light emitting element of FIG. 7.

Referring to FIGS. 6 to 8, the display panel of the display device 10 may include a display substrate 101 and a wavelength conversion member 201 disposed on the display substrate 101.

A barrier layer BR may be disposed on a first substrate 111 of the display substrate 101. The first substrate 111 may be formed of an insulating material such as a polymer resin. For example, the first substrate 111 may be formed of polyimide. The first substrate 111 may be a flexible substrate which can be bent, folded or rolled.

The barrier layer BR is a layer for protecting thin film transistors T1, T2, and T3 and a light emitting element unit LEP from moisture permeating through the first substrate 111 that is susceptible to moisture permeation. The barrier layer BR may be formed as a plurality of inorganic layers that are alternately stacked. For example, the barrier layer BR may be formed of multiple layers in which one or more inorganic layers of a silicon nitride layer, a silicon oxynitride layer, a silicon oxide layer, a titanium oxide layer and/or an aluminum oxide layer are alternately stacked.

Each of the thin film transistors T1, T2, and T3 may be disposed on the barrier layer BR. The thin film transistors T1, T2, and T3 include active layers ACT1, ACT2, ACT3, gate electrodes G1, G2, G3, source electrodes S1, S2, S3, and drain electrodes D1, D2, D3, respectively.

The active layers ACT1, ACT2, ACT3, the source electrodes S1, S2, S3, and the drain electrodes D1, D2, D3, of the thin film transistors T1, T2, and T3 may be disposed on the barrier layer BR. The active layers ACT1, ACT2, and ACT3 of the thin film transistors T1, T2, and T3 include polycrystalline silicon, monocrystalline silicon, low-temperature polycrystalline silicon, amorphous silicon, and/or an oxide semiconductor. The active layers ACT1, ACT2, ACT3 overlapping the gate electrodes G1, G2, G3 in the third direction (Z-axis direction) that is the thickness direction of the first substrate 111 may be defined as a channel region. The source electrodes S1, S2, S3, and the drain electrodes D1, D2, D3, that do not overlap the gate electrodes G1, G2, G3 in the third direction (Z-axis direction) may have conductivity by doping a silicon semiconductor or an oxide semiconductor with ions or impurities.

The gate insulating layer 131 may be disposed on the active layers ACT1, ACT2, ACT3, the source electrodes S1, S2, S3 and the drain electrodes D1, D2, D3 of the thin film transistors T1, T2, and T3. The gate insulating layer 131 may be formed of an inorganic layer, for example, a silicon nitride layer, a silicon oxynitride layer, a silicon oxide layer, a titanium oxide layer, and/or an aluminum oxide layer.

The gate electrodes G1, G2, G3 of the thin film transistors T1, T2, and T3 may be arranged on the gate insulating layer 131. The gate electrodes G1, G2, G3 may overlap the active layers ACT1, ACT2, ACT3 in the third direction (Z-axis direction). The gate electrodes G1, G2, G3 may be formed as a single layer or multiple layers made of molybdenum (Mo), aluminum (Al), chromium (Cr), gold (Au), titanium (Ti), nickel (Ni), neodymium (Nd), and/or copper (Cu), and/or an alloy thereof.

A first interlayer insulating layer 141 may be disposed on the gate electrode G1 of the thin film transistors T1, T2, and T3. The first interlayer insulating layer 141 may be formed of an inorganic layer, for example, a silicon nitride layer, a silicon oxynitride layer, a silicon oxide layer, a titanium oxide layer, or an aluminum oxide layer. The first interlayer insulating layer 141 may be formed of a plurality of inorganic layers.

A capacitor electrode CAE may be disposed on the first interlayer insulating layer 141. The capacitor electrode CAE may overlap the gate electrodes G1, G2, G3 of the thin film transistors T1, T2, and T3 in the third direction (Z-axis direction). Because the first interlayer insulating layer 141 has a suitable dielectric constant (e.g., a predetermined dielectric constant), the capacitor electrode CAE, the gate electrodes G1, G2, G3, and the first interlayer insulating layer 141 disposed therebetween may form a capacitor. The capacitor electrode CAE may be formed as a single layer or multiple layers made of molybdenum (Mo), aluminum (Al), chromium (Cr), gold (Au), titanium (Ti), nickel (Ni), neodymium (Nd), and/or copper (Cu), and/or an alloy thereof.

A second interlayer insulating layer 142 may be disposed on the capacitor electrode CAE. The second interlayer insulating layer 142 may be formed of an inorganic layer, for example, a silicon nitride layer, a silicon oxynitride layer, a silicon oxide layer, a titanium oxide layer, and/or an aluminum oxide layer. The second interlayer insulating layer 142 may be formed of a plurality of inorganic layers.

The first anode connection electrode ADNE1 may be disposed on the second interlayer insulating layer 142. The first anode connection electrode ADNE1 may be respectively connected to the drain electrodes D1, D2, and D3 of the thin film transistors T1, T2, and T3 through a first connection contact hole ANCT1 penetrating the gate insulating layer 131, the first interlayer insulating layer 141, and the second interlayer insulating layer 142. The first anode connection electrode ADNE1 may be formed as a single layer or multiple layers made of molybdenum (Mo), aluminum (Al), chromium (Cr), gold (Au), titanium (Ti), nickel (Ni), neodymium (Nd), and/or copper (Cu), and/or an alloy thereof.

A first planarization layer 160 for flattening a stepped portion formed by the thin film transistors T1, T2, and T3 may be disposed on the first anode connection electrode ADNE1. The first planarization layer 160 may be formed of an organic layer such as acryl resin, epoxy resin, phenolic resin, polyamide resin, polyimide resin, and/or the like.

A second anode connection electrode ADNE2 may be disposed on the first planarization layer 160. The second anode connection electrode ADNE2 may be connected to the first anode connection electrode ADNE1 through a second connection contact hole ANCT2 penetrating the first planarization layer 160. The second anode connection electrode ADNE2 may be formed as a single layer or multiple layers made of molybdenum (Mo), aluminum (Al), chromium (Cr), gold (Au), titanium (Ti), nickel (Ni), neodymium (Nd), and/or copper (Cu), and/or an alloy thereof.

The second planarization layer 180 may be disposed on the second anode connection electrode ADNE2. The second planarization layer 180 may be formed of an organic layer such as acryl resin, epoxy resin, phenolic resin, polyamide resin, polyimide resin, and/or the like.

The light emitting element unit LEP may be formed on the second planarization layer 180. The light emitting element unit LEP may include a plurality of pixel electrodes PE1, PE2, and PE3, the plurality of light emitting elements LE, and a common electrode CE.

The plurality of pixel electrodes PE1, PE2, and PE3 may include the first pixel electrode PE1, the second pixel electrode PE2, and the third pixel electrode PE3. The first pixel electrode PE1, the second pixel electrode PE2, and the third pixel electrode PE3 may serve as a first electrode of the light emitting element LE and may be an anode electrode or a cathode electrode. The first pixel electrode PE1 may be positioned in the first emission area EA1, but at least a part thereof may extend to the non-emission area NEA. The second pixel electrode PE2 may be positioned in the second emission area EA2, but at least a part thereof may extend to the non-emission area NEA. The third pixel electrode PE3 may be positioned in the third emission area EA3, but at least a part thereof may extend to the non-emission area NEA. The first pixel electrode PE1 may penetrate the second planarization layer 180 to be connected to the first switching element T1 via the second anode connection electrode ADNE2 and the first anode connection electrode ADNE1, the second pixel electrode PE2 may penetrate the second planarization layer 180 to be connected to the second switching element T2 via the second anode connection electrode ADNE2 and the first anode connection electrode ADNE1, and the third pixel electrode PE3 may penetrate the second planarization layer 180 to be connected to the third switching element T3 via the second anode connection electrode ADNE2 and the first anode connection electrode ADNE1.

The first pixel electrode PE1, the second pixel electrode PE2, and the third pixel electrode PE3 may be reflective electrodes. The first pixel electrode PE1, the second pixel electrode PE2, and the third pixel electrode PE3 may be formed of titanium (Ti), copper (Cu), or an alloy material of titanium (Ti), and/or copper (Cu). In addition, the first pixel electrode PE1, the second pixel electrode PE2, and the third pixel electrode PE3 may have a stacked structure of titanium (Ti) and copper (Cu). In addition, the first pixel electrode PE1, the second pixel electrode PE2, and the third pixel electrode PE3 may have a stacked structure formed by stacking a material layer having a high work function, such as titanium oxide (TiO₂), indium tin oxide (ITO), indium zinc oxide (IZO), zinc oxide (ZnO), indium tin zinc oxide (ITZO), and/or magnesium oxide (MgO), and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), Titanium (Ti), copper (Cu), and/or a mixture thereof. The material layer having a high work function may be disposed above the reflective material layer and disposed closer to the light emitting element LE. The first pixel electrode PE1, the second pixel electrode PE2, and the third pixel electrode PE3 may have a multilayer structure of ITO/Mg, ITO/MgF, ITO/Ag, and/or ITO/Ag/ITO, but are not limited thereto.

A bank BNL may be positioned on the first pixel electrode PE1, the second pixel electrode PE2, and the third pixel electrode PE3. The bank BNL may include an opening hole exposing the first pixel electrode PE1, an opening hole exposing the second pixel electrode PE2, and an opening hole exposing the third pixel electrode PE3, and may define the first emission area EA1, the second emission area EA2, the third emission area EA3, and the non-emission area NEA. That is, an area of the first pixel electrode PE1 that is not covered by the bank BNL and is exposed may be the first emission area EA1. An area of the second pixel electrode PE2 that is not covered by the bank BNL and is exposed may be the second emission area EA2. An area of the third pixel electrode PE3 that is not covered by the bank BNL and is exposed may be the third emission area EA3. In addition, an area in which the bank BNL is positioned may be the non-emission area NEA.

The bank BNL may include an inorganic insulating material, for example, acrylic resin, epoxy resin, phenolic resin, polyamide resin, polyimide resin, unsaturated polyester resin, polyphenylene resin, polyphenylenesulfide resin, benzocyclobutene (BCB), and/or the like.

In one or more embodiments, the bank BNL may not overlap the color filters CF1, CF2, and CF3 and may overlap a light blocking member BK of the wavelength conversion member 201, which will be described later. In one or more embodiments, the bank BNL may completely overlap the light blocking member BK. In addition, in one or more embodiments, the bank BNL may overlap the first color filter CF1, the second color filter CF2, and the third color filter CF3.

The plurality of light emitting elements LE may be disposed on the first pixel electrode PE1, the second pixel electrode PE2, and the third pixel electrode PE3.

As illustrated in FIGS. 7 and 8, the light emitting element LE may be disposed in each of the first emission area EA1, the second emission area EA2, and the third emission area EA3. The light emitting element LE may be a vertical light emitting diode element elongated in the third direction DR3. That is, the length of the light emitting element LE in the third direction DR3 may be longer than the length thereof in the horizontal direction. The length in the horizontal direction indicates a length in the first direction DR1 or a length in the second direction DR2. For example, the length of the light emitting element LE in the third direction DR3 may be approximately 1 to 5 μm.

The light emitting element LE may be a micro light emitting diode element. The light emitting element LE may include a connection electrode 125, a first semiconductor layer SEM1, an electron blocking layer EBL, an active layer MQW, a superlattice layer SLT, a second semiconductor layer SEM2, and a third semiconductor layer SEM3, in the thickness direction of the display substrate 101, that is, the third direction DR3. The connection electrode 125, the first semiconductor layer SEM1, the electron blocking layer EBL, the active layer MQW, the superlattice layer SLT, the second semiconductor layer SEM2, and the third semiconductor layer SEM3 may be sequentially stacked in the third direction DR3.

The light emitting element LE may have a cylindrical shape that is longer in width than in height, a disc shape, or a rod shape. However, the present disclosure is not limited thereto, and the light emitting element LE may have various shapes, such as a rod shape, a wire shape, a tube shape, a polygonal prism shape such as a regular cube, a rectangular parallelepiped and a hexagonal prism, or a shape extending in one direction and having a partially inclined outer surface.

The connection electrode 125 may be disposed on each of the plurality of pixel electrodes PE1, PE2, and PE3. Hereinafter, the light emitting element LE disposed on the first pixel electrode PE1 will be described as an example.

The connection electrode 125 may be on the first pixel electrode PE1 to be connected to the first pixel electrode, so that the light emitting element LE may receive an emission signal. The connection electrode 125 may be an ohmic connection electrode. However, the present disclosure is not limited thereto, and it may be a Schottky connection electrode. The light emitting element LE may include at least one connection electrode 125. FIGS. 7 and 8 illustrate that the light emitting element LE includes one connection electrode 125, but is not limited thereto. In some cases, the light emitting element LE may include a larger number of connection electrodes 125 or may not have the connection electrode 125. The following description of the light emitting element LE may be equally applied even if the number of connection electrodes 125 is different or other structures are further included.

When the light emitting element LE is electrically connected to the first pixel electrode PE1 in the display device 10 according to one or more embodiments, the connection electrode 125 may reduce the resistance and improve the adhesion between the light emitting element LE and the first pixel electrode PE1. The connection electrode 125 may include a conductive metal oxide. For example, the connection electrode 125 may be ITO. Because the connection electrode 125 is directly in contact with and connected to the lower first pixel electrode PE1, the connection electrode 125 may be made of the same material as the first pixel electrode PE1. In addition, the connection electrode 125 may selectively further include a reflective electrode made of a metal material having a high reflectivity such as aluminum (Al) and/or a diffusion barrier layer including nickel (Ni). Accordingly, adhesion between the connection electrode 125 and the first pixel electrode PE1 may be improved, and thus a contact characteristic may be increased.

Referring to FIG. 8, in one or more embodiments, the first pixel electrode PE1 may include a lower electrode layer P1, a reflective layer P2, and an upper electrode layer P3. The lower electrode layer P1 may be disposed at the lowermost portion of the first pixel electrode PE1 and may be electrically connected from the switching element. The lower electrode layer P1 may include a metal oxide, and may include, for example, titanium oxide (TiO₂), indium tin oxide (ITO), indium zinc oxide (IZO), zinc oxide (ZnO), indium tin zinc oxide (ITZO), magnesium oxide (MgO), and/or the like.

The reflective layer P2 may be disposed on the lower electrode layer P1 to reflect light emitted from the light emitting element LE upward. The reflective layer P2 may include a metal having high reflectivity, may include, for example, silver (Ag), magnesium (Mg), aluminum (Al), platinum (Pt), lead (Pd), gold (Au), nickel. (Ni), neodium (Nd), iridium (Ir), chromium (Cr), lithium (Li), calcium (Ca), and/or a mixture thereof.

The upper electrode layer P3 may be disposed on the reflective layer P2 and may be directly in contact with the light emitting element LE. The upper electrode layer P3 may be disposed between the reflective layer P2 and the connection electrode 125 of the light emitting element LE, and may be directly in contact with the connection electrode 125. As described above, the connection electrode 125 is made of a metal oxide, and the upper electrode layer P3 may also be made of a metal oxide in the same way as the connection electrode 125.

The upper electrode layer P3 may be formed of titanium (Ti), copper (Cu), or an alloy material of titanium (Ti), and/or copper (Cu). In addition, the upper electrode layer P3 may have a stacked structure of titanium (Ti) and/or copper (Cu). In addition, the upper electrode layer P3 may include titanium oxide (TiO₂), indium tin oxide (ITO), indium zinc oxide (IZO), zinc oxide (ZnO), indium tin zinc oxide (ITZO), and/or magnesium oxide (MgO). In one or more embodiments, when the connection electrode 125 is made of ITO, the first pixel electrode PE1 may have a multilayer structure of ITO/Ag/ITO.

The first semiconductor layer SEM1 may be disposed on the connection electrode 125. The first semiconductor layer SEM1 may be a p-type semiconductor, and may include a semiconductor material having a chemical formula of AlxGayIn1-x-yN (0≤x≤1, 0≤y≤1, 0≤x+y≤1). For example, the semiconductor material may be any one or more of p-type doped AlGaInN, GaN, AlGaN, InGaN, AlN, and/or InN. The first semiconductor layer SEM1 may be doped with a p-type dopant, and the p-type dopant may be Mg, Zn, Ca, Se, Ba, and/or the like. For example, the first semiconductor layer SEM1 may be p-GaN doped with p-type Mg. The thickness of the first semiconductor layer SEM1 may be in a range of 30 nm to 200 nm, but is not limited thereto.

The electron blocking layer EBL may be disposed on the first semiconductor layer SEM1. The electron blocking layer EBL may be a layer for suppressing or preventing too many electrons from flowing into the active layer MQW. For example, the electron blocking layer EBL may be p-AlGaN doped with p-type Mg. The thickness of the electron blocking layer EBL may be within a range of 10 nm to 50 nm, but the present disclosure is not limited thereto. Further, the electron blocking layer EBL may be omitted.

The active layer MQW may be disposed on the electron blocking layer EBL. The active layer MQW may emit light by coupling of electron-hole pairs according to an electrical signal applied through the first semiconductor layer SEM1 and the second semiconductor layer SEM2.

The active layer MQW may include a material having a single or multiple quantum well structure. When the active layer MQW contains a material having a multiple quantum well structure, the active layer MQW may have the structure in which a plurality of well layers and barrier layers are alternately laminated. At this time, the well layer may be formed of InGaN, and the barrier layer may be formed of GaN or AlGaN, but the present disclosure is not limited thereto. The thickness of the well layer may be approximately 1 to 4 nm, and the thickness of the barrier layer may be 3 nm to 10 nm.

Alternatively, the active layer MQW may have a structure in which semiconductor materials having large band gap energy and semiconductor materials having small band gap energy are alternately stacked, and may include other Group Ill to Group V semiconductor materials according to the wavelength band of the emitted light. The light emitted by the active layer MQW is not limited to the first light, and in some cases, the second light (e.g., a light of the green wavelength band) or the third light (e.g., a light of the red wavelength band) may be emitted.

Specifically, the color of the light emitted from the active layer MQW may vary according to the content of indium (In). For example, as the content of indium (In) increases or becomes higher, the wavelength band of light emitted by the active layer may shift to a red wavelength band, and as the content of indium (In) decreases or becomes lower, the wavelength band of light emitted by the active layer may shift to a blue wavelength band.

For example, when the content of indium (In) is 35% or more, the active layer MQW may emit the first light in the red wavelength band having a main peak wavelength in a range of approximately 600 nm to 750 nm. Alternatively, when the content of indium (In) is 25%, the active layer MQW may emit the second light in the green wavelength band having a main peak wavelength in a range of approximately 480 nm to 560 nm. Alternatively, when the content of indium (In) is 15% or less, the active layer MQW may emit the third light in the blue wavelength band having a main peak wavelength in a range of approximately 370 nm to 460 nm. An example in which the active layer MQW emits light in the blue wavelength band having a main peak wavelength of approximately 370 nm to 460 nm will be described with reference to FIG. 6.

The superlattice layer SLT may be disposed on the active layer MQW. The superlattice layer SLT may be a layer for relieving stress between the second semiconductor layer SEM2 and the active layer MQW. For example, the superlattice layer SLT may be formed of InGaN and/or GaN. The thickness of the superlattice layer SLT may be about 50 nm to 200 nm. The superlattice layer SLT may be omitted.

The second semiconductor layer SEM2 may be disposed on the superlattice layer SLT. The second semiconductor layer SEM2 may be an n-type semiconductor. The second semiconductor layer SEM2 may include a semiconductor material having a chemical formula of AlxGayIn1-x-yN (0≤x≤1, 0≤y≤1, 0≤x+y≤1). For example, it may be one or more of an n-type doped AlGaInN, GaN, AlGaN, InGaN, AlN, and/or InN. The second semiconductor layer SEM2 may be doped with an n-type dopant, and the n-type dopant may be Si, Ge, Sn, and/or the like. For example, the second semiconductor layer SEM2 may be n-GaN doped with n-type Si. The thickness of the second semiconductor layer SEM2 may be within a range of 2 μm to 4 μm, but the present disclosure is not limited thereto.

The third semiconductor layer SEM3 may be disposed on the second semiconductor layer SEM2. The third semiconductor layer SEM3 may be disposed between the second semiconductor layer SEM2 and the common electrode CE. The third semiconductor layer SEM3 may be an undoped semiconductor. The third semiconductor layer SEM3 may contain the same material as that of the second semiconductor layer SEM2, and may contain a material that is not doped with an n-type or p-type dopant. In one or more embodiments, the third common semiconductor layer SEM3 may be, but is not limited to, at least one of undoped InAlGaN, GaN, AlGaN, InGaN, AlN, and/or InN.

A planarization layer PLL may be disposed on the bank BNL and the plurality of pixel electrodes PE1, PE2, and PE3. The planarization layer PLL may planarize a lower step so that the common electrode CE, which will be described later, may be formed. The planarization layer PLL may be formed to have a suitable height (e.g., a predetermined height) so that at least a part, for example, an upper portion, of the plurality of light emitting elements LE, may protrude above the planarization layer PLL. That is, the height of the planarization layer PLL with respect to the top surface of the first pixel electrode PE1 may be smaller than the height of the light emitting element LE in the third direction DR3.

The planarization layer PLL may include an organic material to planarize the lower step. For example, the planarization layer PLL may include acrylic resin, epoxy resin, phenolic resin, polyamide resin, polyimide resin, unsaturated polyester resin, polyphenylene resin, polyphenylenesulfide resin, benzocyclobutene (BCB), and/or the like.

The common electrode CE may be disposed on the planarization layer PLL and the plurality of light emitting elements LE. Specifically, the common electrode CE may be disposed on one surface of the first substrate 111 on which the light emitting element LE is formed, and may be disposed entirely in the display area DPA and the non-display area NDA. The common electrode CE is disposed to overlap each of the emission areas EA1, EA2, and EA3 in the display area DPA, and may have a thin thickness to allow light to be emitted.

The common electrode CE may be directly disposed on the top surface and the side surface of the plurality of light emitting elements LE. The common electrode CE may be directly in contact with the second semiconductor layer SEM2 on the side surfaces of the light emitting element LE and the third semiconductor layer SEM3 on the top surface and the side surfaces of the light emitting element LE. As illustrated in FIG. 6, the common electrode CE may be a common layer that covers the plurality of light emitting elements LE and is disposed by commonly connecting the plurality of light emitting elements LE. Because the second semiconductor layer SEM2 having conductivity has a patterned structure in each of the light emitting elements LE, the common electrode CE may be directly in contact with the side surface of the second semiconductor layer SEM2 of each of the light emitting elements LE so that a common voltage may be applied to each of the light emitting elements LE.

Because the common electrode CE is entirely disposed on the first substrate 111 and a common voltage is applied, the common electrode CE may include a material having a low resistance. In addition, the common electrode CE may be formed to have a thin thickness to allow light to pass therethrough. For example, the common electrode CE may include a material having a low resistance, such as aluminum (Al), silver (Ag), copper (Cu), and/or the like. The thickness of the common electrode CE may be approximately 10 Å to 200 Å, but is not limited thereto.

The above-described light emitting elements LE may be supplied with a pixel voltage or an anode voltage from a pixel electrode through the connection electrode 125, and may be supplied with a common voltage through the common electrode CE. The light emitting element LE may emit light with a desired luminance (e.g., a predetermined luminance) according to a voltage difference between the pixel voltage and the common voltage.

In the described embodiment, by disposing the plurality of light emitting elements LE, that is, inorganic light emitting diodes, on the pixel electrodes PE1, PE2, and PE3, the disadvantages of organic light emitting diodes, which may be vulnerable to external moisture or oxygen, may be excluded, and lifespan and reliability may be improved.

In one or more embodiments, the first organic layer FOL may be disposed on the bank BNL disposed in the non-emission area NEA.

The first organic layer FOL may overlap the non-emission area NEA in the third direction DR3 and may be disposed not to overlap the emission areas EA1, EA2, and EA3. The first organic layer FOL may be disposed directly on the bank BNL and may be disposed to be spaced apart from a plurality of adjacent pixel electrodes PE1, PE2, and PE3. The first organic layer FOL may be disposed on the entire first substrate 111, and may be disposed to be around (e.g., to surround) the plurality of emission areas EA1, EA2, and EA3. The first organic layer FOL may be disposed in a lattice shape as a whole.

The first organic layer FOL may serve to detach the plurality of light emitting elements LE in contact with the first organic layer FOL, which is the non-emission area NEA, as will be described in a fabricating process to be described later. When the laser light is irradiated, the first organic layer FOL absorbs energy and instantaneously increases its temperature to be ablated. Accordingly, the plurality of light emitting elements LE in contact with the top surface of the first organic layer FOL may be detached from the top surface of the first organic layer FOL.

The first organic layer FOL may contain a polyimide-based compound. The polyimide-based compound of the first organic layer FOL may have a cyano group to absorb light having a wavelength of 308 nm, e.g., laser light. In one or more embodiments, each of the first organic layer FOL and the bank BNL may include a polyimide-based compound, but may include different polyimide-based compounds. For example, the bank BNL may be formed of a polyimide-based compound not including a cyano group, and the first organic layer FOL may be formed of a polyimide-based compound including a cyano group. For laser light having a wavelength of 308 nm, the transmittance of the first organic layer FOL may be less than the transmittance of the bank BNL, the transmittance of the bank BNL is about 60% or more, and the transmittance of the first organic layer FOL may be 0%. In addition, the absorption rate of the first organic layer FOL with respect to laser light having a wavelength of 308 nm may be 100%. The first organic layer FOL may have a thickness in a range of about 2 Å to 10 μm. When the thickness of the first organic layer FOL is 2 Å or more, the absorption rate of laser light having a wavelength of 308 nm may be improved. When the thickness of the first organic layer FOL is 10 μm or less, the height difference between the first organic layer FOL and the pixel electrode PE1 may be prevented from increasing, so that the light emitting element LE may be easily adhered onto the pixel electrode in a process to be described later.

The wavelength conversion member 201 may be disposed on the light emitting element unit LEP. The wavelength conversion member 201 may include a partition wall PW, a wavelength conversion layer QDL, the color filters CF1, CF2, and CF3, the light blocking member BK, and a first passivation layer PTL.

The partition wall PW may be disposed on the common electrode CE of the display area DPA, and may partition the plurality of emission areas EA1, EA2, and EA2 together with the bank BNL. The partition wall PW may be disposed to extend in the first direction DR1 and the second direction DR2, and may be formed in a grid pattern in the entire display area DPA. Further, the partition wall PW may not overlap the plurality of emission areas EA1, EA2, and EA3, and may overlap the non-emission area NEA.

The partition wall PW may include a plurality of opening holes OP1, OP2, and OP3 exposing the lower common electrode CE. The plurality of opening holes OP1, OP2, and OP3 may include a first opening hole OP1 overlapping the first emission area EA1, a second opening hole OP2 overlapping the second emission area EA2, and a third opening hole OP3 overlapping the third emission area EA3. Here, the plurality of opening holes OP1, OP2, and OP3 may correspond to the plurality of emission areas EA1, EA2, and EA3. That is, the first opening hole OP1 may correspond to the first emission area EA1, the second opening hole OP2 may correspond to the second emission area EA2, and the third opening hole OP3 may correspond to the third emission area EA3.

The partition wall PW may serve to provide a space for first and second wavelength conversion layers QDL1 and QDL2 to be formed. To this end, the partition wall PW may have a suitable thickness (e.g., a predetermined thickness). For example, the thickness of the partition wall PW may be in the range of 1 μm to 10 μm.

The partition wall PW may contain an organic insulating material to have a predetermined thickness. The organic insulating material may contain, for example, epoxy resin, acrylic resin, cardo resin or imide resin.

The first wavelength conversion layer QDL1 may be disposed in each of the first opening holes OP1. The first wavelength conversion layer QDL1 may be formed of an island pattern in a shape of dots spaced from each other. The first wavelength conversion layer QDL1 may include a first base resin BRS1 and a first wavelength conversion particle WCP1. The first base resin BRS1 may include a light-transmissive organic material. For example, the first base resin BRS1 may contain epoxy resin, acrylic resin, cardo resin, or imide resin. The first wavelength conversion particle WCP1 may be a quantum dot (QD), a quantum rod, a fluorescent material, or a phosphorescent material. For example, a quantum dot may be a particulate material that emits light of a specific color when an electron transitions from a conduction band to a valence band.

The quantum dot may be a semiconductor nanocrystal material. The quantum dot may have a specific band gap according to its composition and size. Thus, the quantum dot may absorb light and then emit light having an intrinsic wavelength. Examples of semiconductor nanocrystal of quantum dots may include Group IV nanocrystal, Group II-VI compound nanocrystal, Group III-V compound nanocrystal, Group IV-VI nanocrystal, a combination thereof, and/or the like.

The first wavelength conversion layer QDL1 may be formed in the first opening hole OP1 of the first emission area EA1. The first wavelength conversion layer QDL1 may emit light by converting or shifting the peak wavelength of incident light to another specific peak wavelength. The first wavelength conversion layer QDL1 may convert a portion of the blue light emitted from the light emitting element LE into light similar to red light, which is the first light. The first wavelength conversion layer QDL1 may emit light similar to red light and thus may perform conversion into red light, which is the first light, through the first color filter CF1.

The second wavelength conversion layer QDL2 may be disposed in each of the second opening holes OP2. The second wavelength conversion layer QDL2 may be formed of an island pattern in a shape of dots spaced from each other. For example, the second wavelength conversion layer QDL2 may be disposed to overlap the second emission area EA2. The second wavelength conversion layer QDL2 may include a second base resin BRS2 and a second wavelength conversion particle WCP2. The second base resin BRS2 may contain a light-transmissive organic material. Accordingly, the second wavelength conversion layer QDL2 may emit light by converting or shifting the peak wavelength of incident light to another specific peak wavelength. The second wavelength conversion layer QDL2 may convert a portion of the blue light emitted from the light emitting element LE into light similar to green light, which is the second light. The second wavelength conversion layer QDL2 may emit light similar to green light and thus may perform conversion into red light, which is the first light, through the second color filter CF2.

In the third emission area EA3, only a transparent light-transmissive organic material may be formed in the third opening hole OP3 so that the blue light emitted from the light emitting element LE may be emitted through the third color filter CF3 as it is.

The plurality of color filters CF1, CF2, and CF3 may be disposed on the partition wall PW and the first and second wavelength conversion layers QDL1 and QDL2. The plurality of color filters CF1, CF2, and CF3 may be disposed to overlap the plurality of opening holes OP1, OP2, OP3 and the first and second wavelength conversion layers QDL1 and QDL2. The plurality of color filters CF1, CF2, and CF3 may include a first color filter CF1, a second color filter CF2, and a third color filter CF3.

The first color filter CF1 may be disposed to overlap the first emission area EA1. In addition, the first color filter CF1 may be disposed on the first opening hole OP1 of the partition wall PW to overlap the first opening hole OP1. The first color filter CF1 may transmit the first light emitted from the light emitting element LE and absorb or block the second light and the third light. For example, the first color filter CF1 may transmit light of a blue wavelength band and absorb or block light of other wavelength bands such as green and red.

The second color filter CF2 may be disposed to overlap the second emission area EA2. In addition, the second color filter CF2 may be disposed on the second opening hole OP2 of the partition wall PW to overlap the second opening hole OP2. The second color filter CF2 may transmit the second light and absorb or block the first light and the third light. For example, the second color filter CF2 may transmit light of a green wavelength band and absorb or block light of other wavelength bands such as blue and red.

The third color filter CF3 may be disposed to overlap the third emission area EA3. In addition, the third color filter CF3 may be disposed on the third opening hole OP3 of the partition wall PW to overlap the third opening hole OP3. The third color filter CF3 may transmit the third light and absorb or block the first light and the second light. For example, the third color filter CF3 may transmit light of a red wavelength band and absorb or block light of other wavelength bands such as blue and green.

A planar area of each of the plurality of color filters CF1, CF2, and CF3 may be larger than a planar area of each of the plurality of emission areas EA1, EA2, and EA3. For example, the first color filter CF1 may have a larger planar area than the first emission area EA1. The second color filter CF2 may have a larger planar area than the second emission area EA2. The third color filter CF3 may have a larger planar area than the third emission area EA3. However, the present disclosure is not limited thereto, and a planar area of each of the plurality of color filters CF1, CF2, and CF3 may be the same as a planar area of each of the plurality of emission areas EA1, EA2, and EA3.

Referring to FIG. 6, the light blocking member BK may be disposed on the partition wall PW. The light blocking member BK may overlap the non-emission area NEA to block transmission of light. The light blocking member BK may be disposed approximately in a lattice shape in a plan view similar to the bank BNL or the partition wall PW. The light blocking member BK may be disposed to overlap the bank BNL, the first organic layer FOL, and the partition wall PW, and may not overlap the emission areas EA1, EA2, and EA3.

In one or more embodiments, the light blocking member BK may contain an organic light blocking material, and may be formed by a process of coating and exposing the organic light blocking material. The light blocking member BK may include a dye or a pigment having a light blocking property, and may be a black matrix. At least a part of the light blocking member BK may overlap the adjacent color filters CF1, CF2, and CF3, and the color filters CF1, CF2, and CF3 may be disposed on at least a part of the light blocking member BK.

The first passivation layer PTL may be disposed on the plurality of color filters CF1, CF2, and CF3 and the light blocking member BK. The first passivation layer PTL may be disposed on the uppermost portion of the display device 10 to protect the lower plurality of color filters CF1, CF2, and CF3 and the light blocking member BK. One surface, for example, a bottom surface of the first passivation layer PTL may be in contact with the top surface of each of the plurality of color filters CF1, CF2, and CF3 and the light blocking member BK.

The first passivation layer PTL may include an inorganic insulating material to protect the plurality of color filters CF1, CF2, and CF3 and the light blocking member BK. For example, the first passivation layer PTL may include silicon oxide (SiOx), silicon nitride (SiNx), silicon oxynitride (SiOxNy), aluminum oxide (AlxOy), aluminum nitride (AlN), and/or the like, but is not limited thereto. The first passivation layer PTF1 may have a suitable thickness (e.g., a predetermined thickness), for example, in a range of 0.01 μm to 1 μm. However, the present disclosure is not limited thereto.

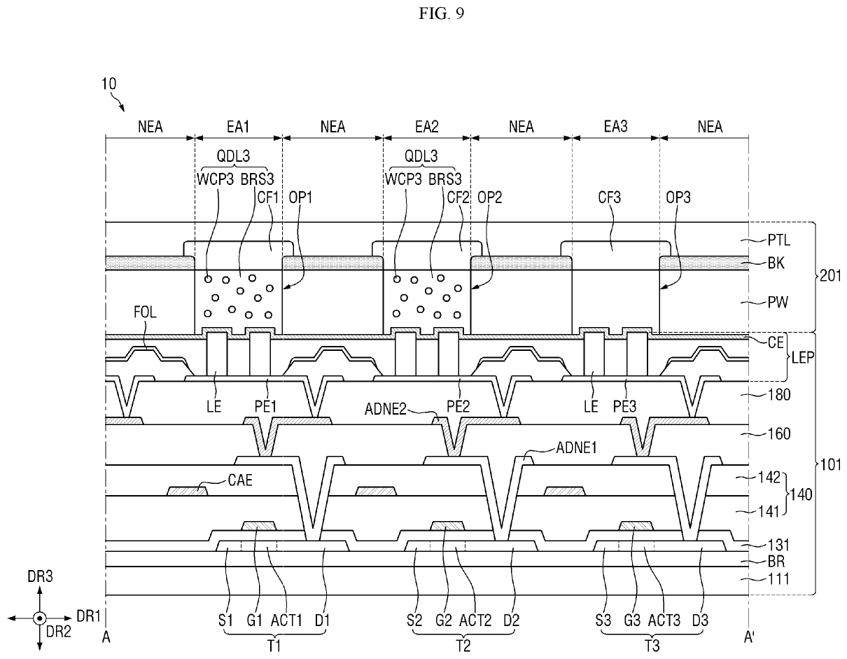

FIG. 9 is a cross-sectional view schematically illustrating a cross section taken along the line A-A′ of FIG. 2 according to another embodiment.

Referring to FIG. 9, a third wavelength conversion layer QDL3 may be disposed in each of the first and second opening holes OP1 and OP2.

The third wavelength conversion layer QDL3 may emit light by converting or shifting the peak wavelength of incident light to another specific peak wavelength. The third wavelength conversion layer QDL3 may convert a portion of the first blue light emitted from the light emitting element LE into the fourth yellow light. In the third wavelength conversion layer QDL3, the first light and the fourth light may be mixed to emit the fifth white light. The fifth light is converted into the first light through the first color filter CF1 and is converted into the second light through the second color filter CF2.

The third wavelength conversion layer QDL3 may be disposed in each of the first and second opening holes OP1 and OP2, and may be spaced from each other. That is, the third wavelength conversion layer QDL3 may be formed of an island pattern in a shape of dots spaced from each other. For example, the third wavelength conversion layer QDL3 may be disposed only in each of the first opening hole OP1 and the second opening hole OP2, in a one-to-one correspondence. In addition, the third wavelength conversion layer QDL3 may be disposed to overlap each of the first emission area EA1 and the second emission area EA2. In one or more embodiments, each of the third wavelength conversion layers QDL3 may completely overlap the first emission area EA1 and the second emission area EA2.

The third wavelength conversion layer QDL3 may include a third base resin BRS3 and third wavelength conversion particles WCP3. The third base resin BRS3 may contain a light-transmissive organic material. For example, the third base resin BRS3 may contain epoxy resin, acrylic resin, cardo resin, and/or imide resin.

The third wavelength conversion particle WCP3 may convert the first light incident from the light emitting element LE into the fourth light. For example, the third wavelength conversion particle WCP3 may convert light of a blue wavelength band into light of a yellow wavelength band. The third wavelength conversion particle WCP3 may be a quantum dot (QD), a quantum rod, a fluorescent material, or a phosphorescent material. For example, a quantum dot may be a particulate material that emits light of a specific color when an electron transitions from a conduction band to a valence band.

As the thickness of the third wavelength conversion layer QDL3 increases in the third direction DR3, the content of the third wavelength conversion particles WCP3 included in the wavelength conversion layer QDL increases, so that the light conversion efficiency of the third wavelength conversion layer QDL3 may increase. Accordingly, the thickness of the third wavelength conversion layer QDL3 is preferably set in consideration of the light conversion efficiency of the third wavelength conversion layer QDL3.

In the above-described third wavelength conversion layer QDL3, a part of the first light emitted from the light emitting element LE may be converted into fourth light in the third wavelength conversion layer QDL3. The third wavelength conversion layer QDL3 may emit white fifth light by mixing the first light and the fourth light. For the fifth light emitted from the third wavelength conversion layer QDL3, the first color filter CF1 to be described later may transmit only the first light, and the second color filter CF2 may transmit only the second light. Accordingly, the light emitted from the wavelength conversion member 201 may be the red and green light of the first light and the second light. In the third emission area EA3, only a transparent light-transmissive organic material may be formed in the third opening hole OP3 so that the blue light emitted from the light emitting element LE may be emitted through the third color filter CF3 as it is. Accordingly, full colors may be produced.

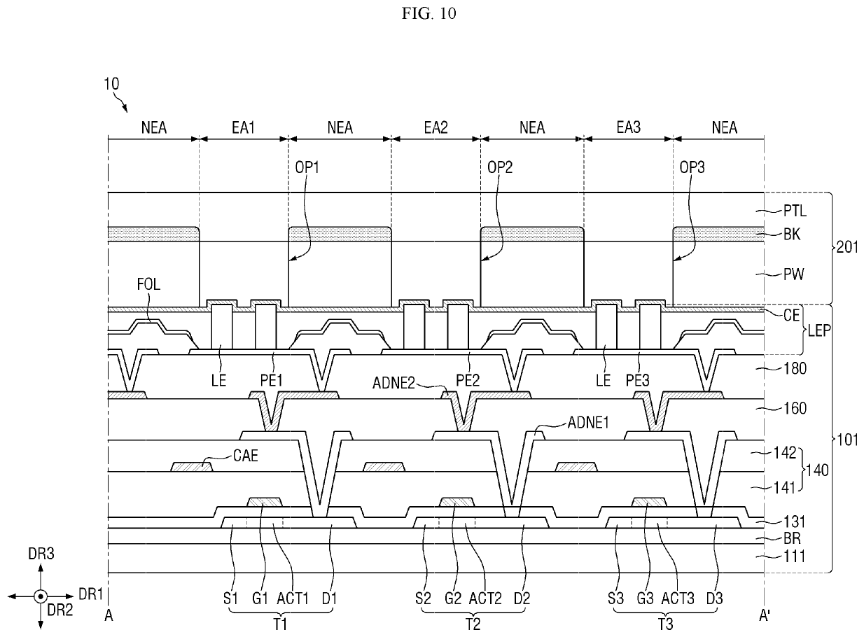

FIG. 10 is a cross-sectional view schematically illustrating a cross section taken along the line A-A′ of FIG. 2 according to one or more embodiments.

As described above, the color of the light emitted from the active layer MQW of each light emitting element LE may vary according to the content of indium (In). As the content of indium (In) increases or becomes higher, the wavelength band of light emitted by the active layer may shift to a red wavelength band, and as the content of indium (In) decreases or becomes lower, the wavelength band of light emitted by the active layer may shift to a blue wavelength band. Accordingly, when the content of indium (In) in the active layer MQW of each light emitting element LE formed in the first emission area EA1 is 25% or more, a first light in a red wavelength band with the main peak wavelength in a range of approximately 600 nm to 750 nm may be emitted.

When the content of indium (In) in the active layer MQW of each light emitting element LE formed in the second emission area EA2 is 25%, a second light in a green wavelength band with the main peak wavelength in a range of approximately 480 nm to 560 nm may be emitted.

When the content of indium (In) in the active layer MQW of each light emitting element LE formed in the third emission area EA3 is 15% or less, the active layer MQW may emit a third light in a blue wavelength band with the main peak wavelength in a range of approximately 370 nm to 460 nm.

Each light emitting element LE formed in the first emission area EA1 may emit a first light of a red wavelength band, each light emitting element LE formed in the second emission area EA2 may emit a second light of a green wavelength band, and each light emitting element LE formed in the third emission area EA3 may emit a third light of a blue wavelength band. In this case, the color filters CF1, CF2, and CF3 may not be formed.

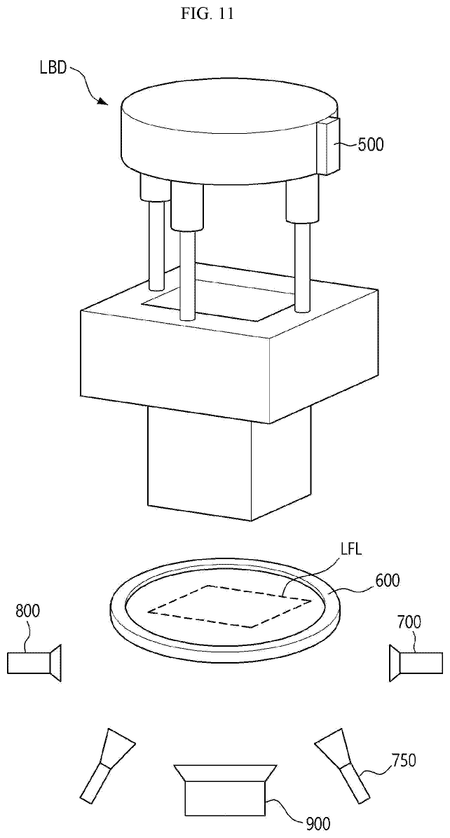

FIG. 11 is a perspective view schematically illustrating an apparatus for fabricating a display panel according to one or more embodiments.

Referring to FIG. 11, the apparatus for fabricating the display panel includes a film fixing module 600, a film pressurizing module LBD, a main processor 500, a first thickness detection module 700, a second thickness detection module 800, a lighting module 750, and an image detection module 900.

The film fixing module 600 fixes a stretched film LFL by pressurizing, in front and rear directions, the outer surface (e.g., the outer peripheral surface) of the stretched film LFL on which the plurality of light emitting elements LE are arranged. The film fixing module 600 may fix the outer surface (e.g., the outer peripheral surface) of the stretched film LFL such that the plurality of light emitting elements LE are disposed in the stretching direction of the stretched film LFL, e.g., in the downward direction of the film fixing module 600.

The film fixing module 600 may be assembled and fixed in a pressing direction of the film pressurizing module LBD, e.g., in a pressing and stretching direction of the stretched film LFL facing the film fixing module 600. Here, the plurality of light emitting elements LE may be disposed in the stretching direction of the stretched film LFL, which is the rear direction of the stretched film LFL.

The film pressurizing module LBD pressurizes the stretched film LFL fixed to the film fixing module 600 in a direction from the front to the rear. The film pressurizing module LBD may pressurize the stretched film LFL in a direction from the front to the rear with a suitable (e.g., preset) pressing force for each pressurization step. For example, the film pressurizing module LBD may primarily pressurize the front surface of the stretched film LFL with a suitable (e.g., preset) first pressing force, and may secondly pressurize the front surface of the stretched film LFL with a second pressing force greater than the first pressing force. In addition, the film pressurizing module LBD may perform pressurization with an increased pressing force by tertiarily pressurizing the front surface of the stretched film LFL with a third pressing force greater than the second pressing force. Here, the film pressurizing module LBD may pressurize the stretched film LFL by gradually increasing the pressing force for each pressurization step in n suitable steps (e.g., n preset steps). Here, n may be a positive integer or a natural number equal to or greater than 1.

The first thickness detection module 700 may be disposed in a stretching direction in which the stretched film LFL is stretched or in one lateral direction in which the stretched film LFL is stretched. The first thickness detection module 700 detects, at each pressurization step, a change in the thickness of the stretched film LFL that is pressurized and stretched by the film pressurizing module LBD for each pressurization step and a modulus of elasticity that varies depending on the thickness change. Then, the first thickness detection module 700 transmits first thickness detection data corresponding to the thickness and the elastic modulus of the stretched film LFL to the main processor 500.

The first thickness detection module 700 may detect the thickness change of the stretched film LFL by using at least one sensor, a light emitting element, and/or the like among at least one ultrasonic sensor, an infrared light emitting element, an infrared reflected light quantity detection sensor, and/or an image sensor. In addition, the first thickness detection module 700 may further include at least one analog to digital (AD) conversion circuit, a microprocessor, and a short-distance communication circuit.

The first thickness detection module 700 detects a first light quantity detection signal corresponding to the thickness change of the stretched film LFL by using at least one sensor, a light emitting element, and/or the like under the control of a microprocessor (e.g., a pre-programmed microprocessor). Then, the first thickness detection module 700 may convert the first light quantity detection signal into a digital data signal to transmit the first thickness detection data corresponding to the thickness change of the stretched film LFL to the main processor 500.

The second thickness detection module 800 may be disposed in a stretching direction in which the stretched film LFL is stretched or in the other lateral direction in which the stretched film LFL is stretched. The second thickness detection module 800 and the first thickness detection module 700 may be disposed side by side on adjacent sides, or may be separately disposed in different lateral directions.

The second thickness detection module 800 detects, at each pressurization step, a change in an adhesive thickness in the front direction of the stretched film LFL that is pressurized and stretched for each pressurization step by the film pressurizing module LBD. Then, the second thickness detection module 800 transmits second thickness detection data corresponding to the adhesive thickness change in the front direction of the stretched film LFL to the main processor 500. To this end, the second thickness detection module 800 may include at least one sensor, a light emitting element, and/or the like from among at least one ultrasonic sensor, a light emitting element, a light receiving element, a reflected light quantity detection sensor, and/or an image sensor. In addition, the second thickness detection module 800 may further include at least one AD conversion circuit, a microprocessor, and a short-distance communication circuit.

The second thickness detection module 800 detects a second light quantity detection signal corresponding to the adhesive thickness change of the stretched film LFL by using at least one light receiving element, a light emitting element, a sensor, and/or the like under the control of a microprocessor (e.g., a pre-programmed microprocessor). Then, the second thickness detection module 800 may convert the second light quantity detection signal into a digital data signal to transmit the second thickness detection data corresponding to the adhesive thickness change in the front direction of the stretched film LFL to the main processor 500.

The image detection module 900 is arranged to face the stretching direction of the stretched film LFL, and photographs the plurality of light emitting elements LE disposed on the stretched film LFL for each stretching and pressurizing step of the stretched film LFL. The image detection module 900 compares and analyzes the arrangement images of the light emitting elements LE obtained at each pressurization step of the stretched film LFL, and detects a change in arrangement information of the light emitting elements LE. Specifically, the image detection module 900 analyzes the arrangement images of the light emitting elements LE for each pressurization step of the stretched film LFL to detect each of damage rate data and transfer rate data of the light emitting elements LE for each pressurization step of the stretched film LFL. In addition, the image detection module 900 may analyze the arrangement images of the light emitting elements LE for each pressurization step of the stretched film LFL to detect density change information of the light emitting elements LE for each pressurization step. The damage rate data, the transfer rate data, and the density change information of the light emitting elements LE for each pressurization step are transmitted to the main processor 500.

The lighting module 750 is disposed adjacent to the image detection module 900 to face the stretching direction of the stretched film LFL, and emits illumination light to the stretched film LFL.

The main processor 500 receives pressing force magnitude information for each pressurization step of the film pressurizing module LBD that pressurizes the stretched film LFL for each pressurization step. Then, the main processor 500 receives, from the first thickness detection module 700, the first thickness detection data corresponding to a change in the thickness or elastic modulus of the stretched film LFL that is pressurized and stretched for each step by the film pressurizing module LBD. Thereafter, the main processor 500 receives, from the second thickness detection module 800, the second thickness detection data corresponding to a change in the adhesive thickness in the front direction of the stretched film LFL. In addition, the main processor 500 receives the damage rate data and the transfer rate data of the light emitting elements LE and the density change information of the light emitting elements LE for each pressurization step of the stretched film LFL through the image detection module 900.

In one or more embodiments, the main processor 500 may receive the arrangement images of the light emitting elements LE obtained for each pressurization step of the stretched film LFL from the image detection module 900. Accordingly, the main processor 500 may analyze the arrangement images of the light emitting elements LE for each pressurization step of the stretched film LFL to detect each of the damage rate data and the transfer rate data of the light emitting elements LE for each pressurization step of the stretched film LFL. In addition, the main processor 500 may analyze the arrangement images of the light emitting elements LE for each pressurization step of the stretched film LFL to detect the density change information of the light emitting elements LE for each pressurization step.

Based on the pressing force magnitude information for each pressurization step of the film pressurizing module LBD, the main processor 500 sorts and databases specifications including type, model name, area, and the like of the stretched film LFL, the first thickness detection data of the stretched film LFL, elastic modulus detection data, and the second thickness detection data which is adhesive thickness detection data. In addition, based on the pressing force magnitude information for each step of the film pressurizing module LBD, the main processor 500 sorts and databases the damage rate data, the transfer rate data, and the density change information of the light emitting elements LE.

The main processor 500 may share and output the specifications including the type, model name, area, and the like of the stretched film LFL, the first and second thickness detection data databased in conformity with the pressing force for each pressurization step, the damage rate data, the transfer rate data, and the density change information of the light emitting elements LE to a separate monitor, server, or the like.

In one or more embodiments, the main processor 500 may store layout shape data including structural features such as pixel size, pixel shape, and pixel arrangement structure of the display substrate 101 for each display panel, and may read the layout shape data of the display substrate 101 for each display panel.

The main processor 500 compares and matches the transfer rate data and the density change information of the light emitting elements LE depending on the pressing force magnitude information for each pressurization step of the stretched film LFL against the layout shape data of the display substrate 101 for each display panel. Accordingly, the main processor 500 may simulate the transfer rate and the arrangement information of the light emitting elements LE transferred to each pixel of the display substrate 101 for each display panel.

The main processor 500 may perform a simulation to shape the layout shape data of the display substrate 101, the transfer rate data and the density change information of the light emitting elements LE into a layout drawing. Accordingly, the main processor 500 may share and output a simulation result image in which the light emitting elements LE of the stretched film LFL are transferred to the pixel shapes of the display substrate 101 to a separate monitor, server, or the like.

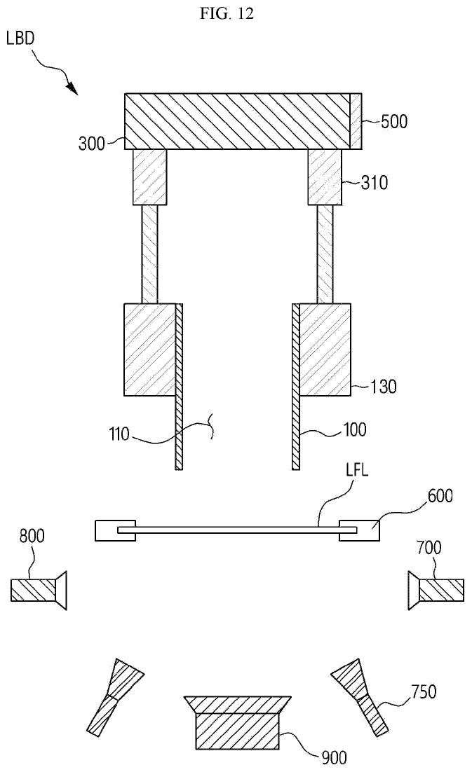

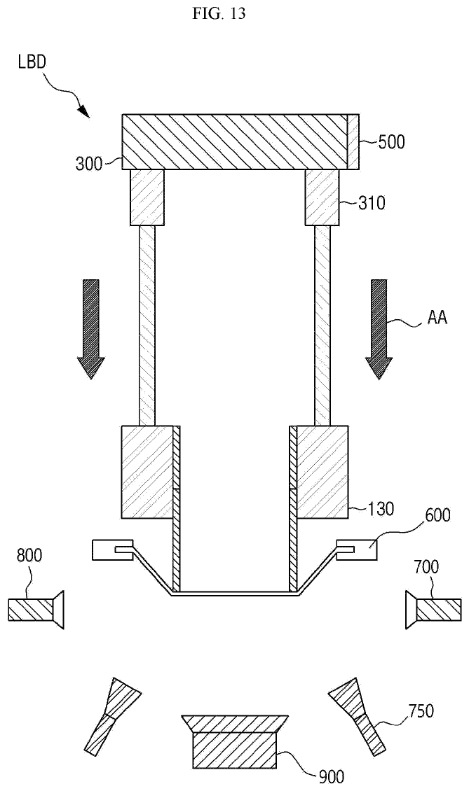

FIG. 12 is a cross-sectional view showing cross-sectional structures of a film fixing module, a film pressurizing module, a main processor, and the like shown in FIG. 11. FIG. 13 is a cross-sectional view showing a process of pressurizing and stretching a stretched film by the film pressurizing module shown in FIG. 12.

Referring to FIGS. 12 and 13, the film pressurizing module LBD includes a pressurizing member 100, a fixing frame 130, a pressurizing driving member 300, and a plurality of pressure regulators 310.

The pressurizing member 100 of the film pressurizing module LBD may be formed in a polygonal tube shape in which an opening 110 having a circular shape or a polygonal shape such as a rectangle is formed. Alternatively, the pressurizing member 100 may be formed in a circular tube shape (e.g., a cylindrical shape). Hereinafter, an example in which the pressurizing member 100 is formed in a rectangular tube shape having a rectangular opening 110 will be described. In addition, the pressurizing member 100 may be disposed in a vertical direction from the ground, and a downward direction toward the ground may be a pressing direction (e.g., direction of arrow AA) of the pressurizing member 100. Alternatively, an upward direction opposite to the ground may be a detaching direction of the pressurizing member 100.

The pressurizing member 100 pressurizes the stretched film LFL fixed to the film fixing module 600 while moving in the pressing direction (e.g., direction of arrow AA) by the plurality of pressure regulators 310 under the control of the pressurizing driving member 300.

The fixing frame 130 is attached or assembled to the outer surface of the pressurizing member 100. The fixing frame 130 may be integrally formed with the pressurizing member 100. The fixing frame 130 is formed to protrude from the outer surface of the pressurizing member 100. The fixing frame 130 may be around (e.g., may surround) the outer surface (e.g., the outer peripheral surface) of the pressurizing member 100 and protrude in a rectangular shape, a hemispherical shape, or the like. The rear or outer surface of the fixing frame 130 is coupled with the pressure regulators 310 of the pressurizing driving member 300. The pressurizing member 100 is moved in the downward pressing direction (e.g., direction of arrow AA) or in the upward detaching direction together with the fixing frame 130, by the driving control of the pressurizing driving member 300 and the pressure regulators 310.

The pressurizing driving member 300 includes a flat support frame and the plurality of pressure regulators 310 attached to the flat support frame. The length of each pressure regulator 310 may be adjusted by adjusting the pressure in a pneumatic or hydraulic manner. The pressurizing driving member 300 moves the pressurizing member 100 and the fixing frame 130 by using the plurality of pressure regulators 310. Specifically, the pressure regulators 310 of the pressurizing driving member 300 are disposed below the flat support frame of the pressurizing driving member 300. The lengths of the pressure regulators 310 are adjusted depending on a change in internal air pressure or hydraulic pressure. The pressurizing driving member 300 may change the length of each pressure regulator 310 to move the pressurizing member 100 and the fixing frame 130 in the downward pressing direction (e.g., direction of arrow AA), or in the upward direction opposite thereto.

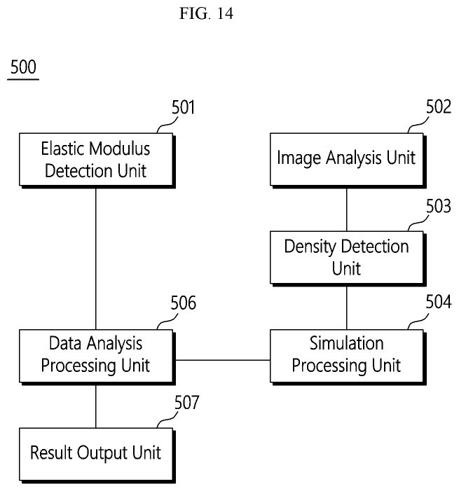

FIG. 14 is a block diagram showing the main processor of FIGS. 11 and 12 in detail.

Referring to FIGS. 14, the main processor 500 includes an elastic modulus detection unit 501, an image analysis unit 502, a density detection unit 503, a simulation processing unit 504, a data analysis processing unit 506, and a result output unit 507.

The elastic modulus detection unit 501 extracts, for each pressurization step, the thickness change value of the stretched film LFL that is pressurized and stretched by the film pressurizing module LBD through the first thickness detection data inputted from the first thickness detection module 700. In addition, the elastic modulus detection unit 501 extracts an elastic modulus value depending on the thickness change of the stretched film LFL through the first thickness detection data. The elastic modulus of the stretched film LFL may be changed in inverse proportion to the thickness change of the stretched film LFL.

The image analysis unit 502 analyzes the arrangement images of the light emitting elements LE inputted from the image detection module 900 to detect each of the damage rate data and the transfer rate data of the light emitting elements LE for each pressurization step of the stretched film LFL.

The image analysis unit 502 analyzes at least one of the arrangement images of the light emitting elements LE and divides and distinguishes each light emitting element LE and the background. For example, the image analysis unit 502 may distinguish each of the light emitting elements LE by dividing and distinguishing similar grayscale values or similar luminance values included in the arrangement image data of the light emitting elements LE. Here, a range of the similar grayscale values or the similar luminance values may be set in advance. Accordingly, the image analysis unit 502 may compare distribution areas or sizes of similar grayscales of the divided light emitting elements LE to classify the images of normally arranged light emitting elements LE, the images of damaged light emitting elements LE, and the images of abnormally arranged light emitting elements LE. The image analysis unit 502 may detect each of the damage rate data and the transfer rate data of the light emitting elements LE for each pressurization step depending on the number of light emitting elements LE that are damaged or abnormally arranged against the number of light emitting elements LE that are normally arranged.

The density detection unit 503 analyzes the arrangement images of the light emitting elements LE to detect the density change information of the light emitting elements LE for each pressurization step of the stretched film LFL. The density detection unit 503 may detect the arrangement density of the light emitting elements LE based on the arrangement area of the light emitting elements LE compared to the total area in at least one of the arrangement images of the light emitting elements LE. In addition, the density detection unit 503 may detect a distance between the light emitting elements LE disposed adjacent to each other compared to the total area in the image in which the light emitting elements LE are disposed.

The data analysis processing unit 506 classifies the specifications including the type, model name, area, and the like of the stretched film LFL. Then, for each specification, the data analysis processing unit 506 sorts and databases the first thickness detection data of the stretched film LFL, the elastic modulus detection data, and the adhesive thickness detection data of the stretched film LFL depending on the pressing force magnitude change for each step of the film pressurizing module LBD.

For example, the data analysis processing unit 506 sets the pressing force magnitude information for each step of the film pressurizing module LBD as a data list for each specification of at least one of the type, model name, or area of the stretched film LFL. Then, the data analysis processing unit 506 may sort and database the first thickness detection data of the stretched film LFL, the elastic modulus detection data, and the adhesive thickness detection data of the stretched film LFL for each set data list.

In addition, the data analysis processing unit 506 may sort and database the damage rate data and the transfer rate data of the light emitting elements LE and the density change information of the light emitting elements LE for each set data list.

The result output unit 507 outputs result data databased from the data analysis processing unit 506 to a separate monitor or server. In other words, the result output unit 507 may output the thickness detection data, the elastic modulus detection data, the adhesive thickness detection data, the damage rate data, the transfer rate data, and the density change information databased based on the specification of the stretched film LFL and the pressing force magnitude information for each pressurization step to a separate monitor, server, or the like.

The simulation processing unit 504 matches and compares the layout shape data including structural features such as pixel size, pixel shape, and pixel arrangement structure of the display substrate 101 for each display panel with the arrangement images of the light emitting elements LE. Then, the simulation processing unit 504 generates a simulation result image in which the light emitting elements LE of the stretched film LFL are transferred to the pixel shapes of the display substrate 101. To this end, the simulation processing unit 504 may store the layout shape data including structural features such as pixel size, pixel shape, and pixel arrangement structure of the display substrate 101 for each display panel, and may read the layout shape data of the display substrate 101 for each display panel.

For example, the simulation processing unit 504 may compare and match the transfer rate data and the density change information of the light emitting elements LE depending on the pressing force magnitude information for each pressurization step of the stretched film LFL compared to the layout shape data of the display substrate 101 for each display panel. Accordingly, the simulation processing unit 504 may additionally simulate the transfer rate and the arrangement information of the light emitting elements LE transferred to each pixel of the display substrate 101 for each display panel. Specifically, the simulation processing unit 504 may shape the layout shape data of the display substrate 101 and the transfer rate data and the density change information of the light emitting elements LE into a layout drawing, and may output the simulation result image in which the light emitting elements LE of the stretched film LFL are transferred to the pixel shapes of the display substrate 101.

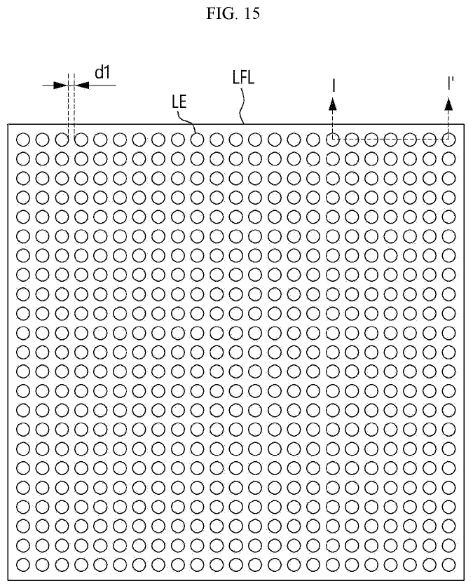

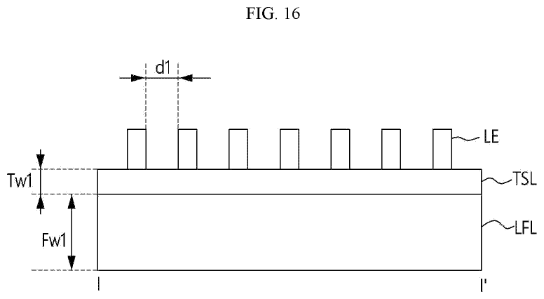

FIG. 15 is a view showing an arrangement image of light emitting elements detected through an image detection module in a first step of pressurizing the stretched film by the film pressurizing module shown in FIG. 11. FIG. 16 is a cross-sectional view showing a cross section along the line I-I′ of FIG. 15.

Specifically, FIGS. 15 and 16 show the cross section of the stretched film LFL and the arrangement image of the light emitting elements in the initial first step in which the stretched film LFL of the film fixing module 600 is pressurized and stretched with the first pressing force by the film pressurizing module LBD.

In the first step in which the stretched film LFL is pressurized with the first pressing force, the plurality of light emitting elements LE disposed on an adhesive TSL of the stretched film LFL may be arranged at first intervals d1. The first interval d1 between the plurality of light emitting elements LE may be a distance formed during formation and fabricating of the plurality of light emitting elements LE.

In the first step of the initial pressurizing, the stretched film LFL is maintained at a first film thickness Fw1, which is the basic fabricating thickness of the stretched film LFL, and the adhesive TSL applied in the front direction of the stretched film LFL may be maintained at a first adhesive thickness Tw1, which is the initial coating thickness.

In the first step of the initial pressurizing, the stretched film LFL may be in a state before being pressurized by the film pressurizing module LBD or in a state of starting to be pressurized by the film pressurizing module LBD. Accordingly, the first interval d1 between the light emitting elements LE, the first film thickness Fw1 of the stretched film LFL, and the first adhesive thickness Tw1 of the adhesive TSL may all be in a state of being maintained in the initial formation process.

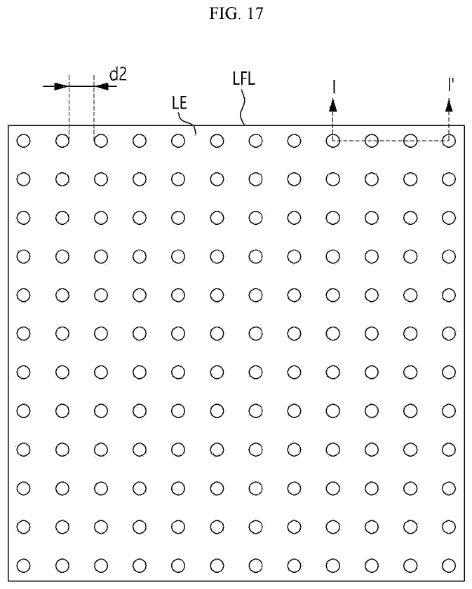

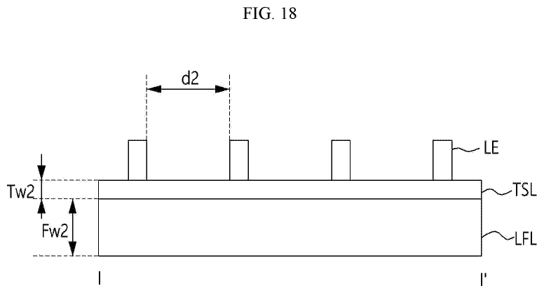

FIG. 17 is a view showing an arrangement image of light emitting elements detected through an image detection module in a second step of pressurizing the stretched film by the film pressurizing module shown in FIG. 11. FIG. 18 is a cross-sectional view showing a cross section along the line I-I′ of FIG. 17.

More specifically, FIGS. 17 and 18 show the cross section of the stretched film LFL and the arrangement image of the light emitting elements in a second step in which the stretched film LFL of the film fixing module 600 is pressurized and stretched with the second pressing force by the film pressurizing module LBD.

In the second step in which the stretched film LFL is pressurized with the second pressing force, the plurality of light emitting elements LE disposed on the adhesive TSL of the stretched film LFL may be arranged at second intervals d2 greater than the first interval d1. The second interval d2 between the plurality of light emitting elements LE may be a distance changed to a greater width than the first interval d1 as the stretched film LFL is stretched with the second pressing force.

In the second step in which the stretched film LFL is pressurized with the second pressing force by the film pressurizing module LBD, the stretched film LFL may be changed to have a second film thickness Fw2 smaller than the first film thickness Fw1, which is the basic fabricating thickness. In addition, the coating thickness of the adhesive TSL applied in the front direction of the stretched film LFL may also be changed to a second adhesive thickness Tw2 smaller than the first adhesive thickness Tw1.

TABLE 1

| | First Pressing | Second Pressing | Third Pressing |
|---|---|---|---|
| | Force (hPa) | Force (hPa) | Force (hPa) |
| Elastic Modulus (k) | 219 | 598 | 1478 |
| Adhesive Thickness | 3 | 6 | 9 |
| (T) | | | |
| Damage Rate (%) | 1 | 5 | 10 |
| Transfer Rate (%) | 99 | 95 | 90 |
| Density (d) | 10 | 20 | 30 |

Referring to Table 1 above, in the first and second steps in which the stretched film LFL is pressurized with the first and second pressing forces by the film pressurizing module LBD, the first thickness detection module 700 detects the thickness change of the stretched film LFL and the elasticity modulus depending on the thickness change at each step. Then, the second thickness detection module 800 detects the adhesive thickness change in the front direction of the stretched film LFL at each step. In one or more embodiments, the image detection module 900 sequentially detects the damage rate data, the transfer rate data, and the density change information of the light emitting elements LE.

In addition, as shown in Table 1, the main processor 500 sorts and databases the thickness or elastic modulus of the stretched film LFL, the adhesive thickness, and the damage rate data, the transfer rate data, and the density change information of the light emitting elements LE based on the pressing force magnitude information for each step of the film pressurizing module LBD.

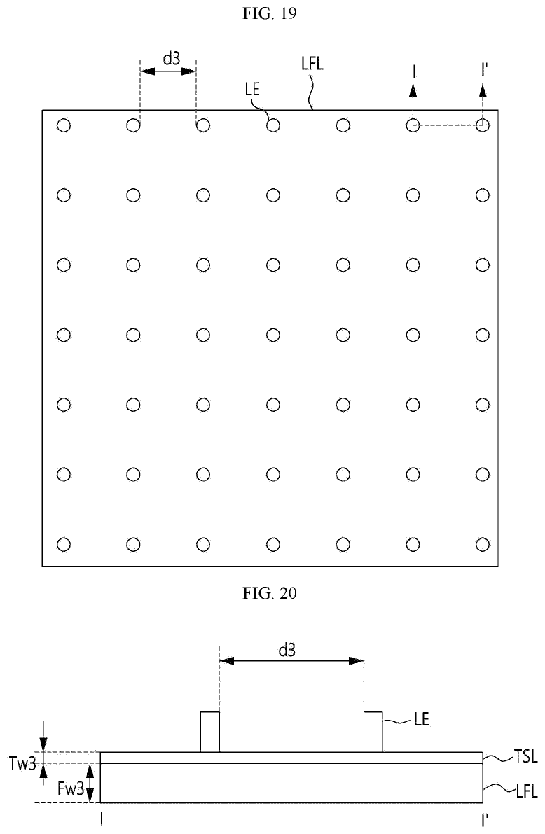

FIG. 19 is a view showing an arrangement image of light emitting elements detected through an image detection module in a third step of pressurizing the stretched film by the film pressurizing module shown in FIG. 11. FIG. 20 is a cross-sectional view showing a cross section along the line I-I′ of FIG. 19.

More specifically, FIGS. 19 and 20 show the cross section of the stretched film LFL and the arrangement image of the light emitting elements in a third step in which the stretched film LFL of the film fixing module 600 is pressurized and stretched with the third pressing force by the film pressurizing module LBD.

In the third step in which the stretched film LFL is pressurized with the third pressing force, the plurality of light emitting elements LE disposed on the adhesive TSL of the stretched film LFL may be arranged at third intervals d3 greater than the second interval d2. The third interval d3 between the plurality of light emitting elements LE may be a distance changed to a greater width than the second interval d2 as the stretched film LFL is stretched with the third pressing force.

In the third step in which the stretched film LFL is pressurized with the third pressing force by the film pressurizing module LBD, the stretched film LFL may be changed to have a third film thickness Fw3 smaller than the second film thickness Fw2 of the second step. In addition, the coating thickness of the adhesive TSL applied in the front direction of the stretched film LFL may also be changed to a third adhesive thickness Tw3 smaller than the second adhesive thickness Tw2.

In the third step in which the stretched film LFL is pressurized with the third pressing force by the film pressurizing module LBD, the first thickness detection module 700 detects the thickness change of the stretched film LFL and the elasticity modulus depending on the thickness change. Similarly, the second thickness detection module 800 detects the adhesive thickness change of the stretched film LFL. In one or more embodiments, the image detection module 900 sequentially detects the damage rate data, the transfer rate data, and the density change information of the light emitting elements LE.

Accordingly, the main processor 500 may sort and database the thickness or elastic modulus of the stretched film LFL, the adhesive thickness, and the damage rate data, the transfer rate data, and the density change information of the light emitting elements LE based on the pressing force magnitude information for each step of the film pressurizing module LBD.

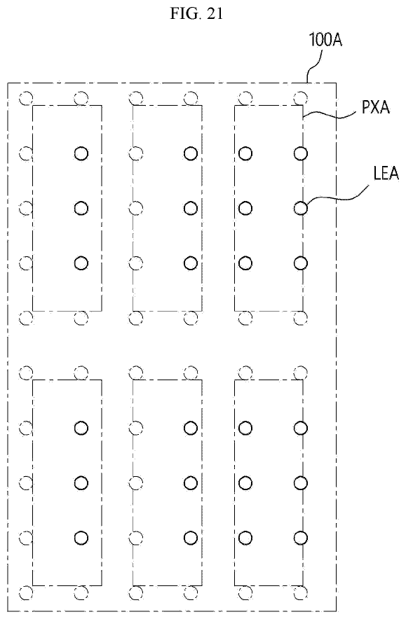

FIG. 21 is a layout diagram showing a simulation result image of a main processor according to one or more embodiments.

Referring to FIG. 21, the simulation processing unit 504 of the main processor 500 according to one or more embodiments matches and compares layout shape data 100A including structural features such as pixel size, pixel shape PXA, and pixel arrangement structure of the display substrate 101 for each display panel with arrangement images LEA of the light emitting elements LE.

For example, the simulation processing unit 504 may match the layout shape data 100A of the display substrate 101 with the arrangement images LEA of the light emitting elements LE to form a layout drawing, and may output the simulation result image in which the light emitting elements LE of the stretched film LFL are transferred to the pixel shapes PXA of the display substrate 101.

Referring to the simulation result image of FIG. 21, it can be confirmed in advance that about three to six light emitting elements LE are irregularly arranged in the pixel shapes PXA of the display substrate 101.

On the other hand, the simulation processing unit 504 may compare and match the transfer rate data and the density change information of the light emitting elements LE depending on the pressing force magnitude information for each pressurization step of the stretched film LFL compared to the layout shape data 100A of the display substrate 101 for each display panel. Accordingly, the simulation processing unit 504 may additionally simulate the transfer rate and the arrangement information of the light emitting elements LE transferred to each pixel of the display substrate 101 for each display panel.

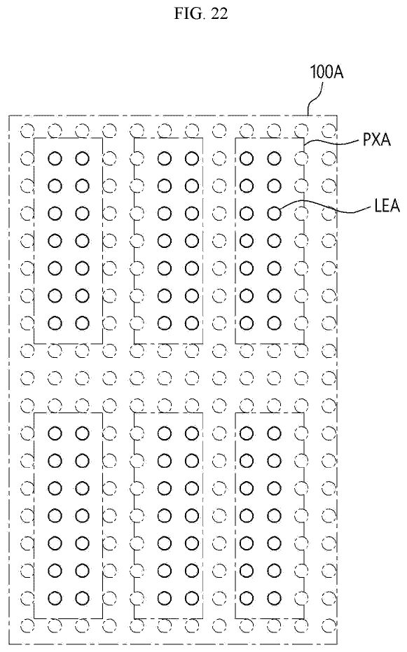

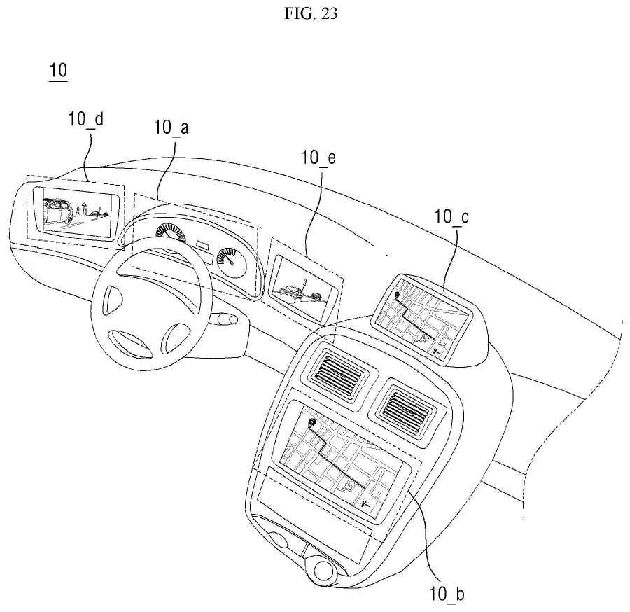

FIG. 22 is a layout diagram showing a simulation result image of a main processor according to one or more embodiments.

Referring to FIG. 22, the simulation processing unit 504 according to one or more embodiments matches and compares the layout shape data 100A including the pixel shapes PXA of the display substrate 101 for each display panel with the arrangement images LEA of light emitting elements LE. For example, the simulation processing unit 504 may match the layout shape data 100A of the display substrate 101 with the arrangement images LEA of the light emitting elements LE to form a layout drawing, and may output the simulation result image in which the light emitting elements LE of the stretched film LFL are transferred to the pixel shapes PXA of the display substrate 101.

Referring to the simulation result image of FIG. 22, it can be confirmed in advance that ten or more light emitting elements LE are regularly arranged in the pixel shapes PXA of the display substrate 101.

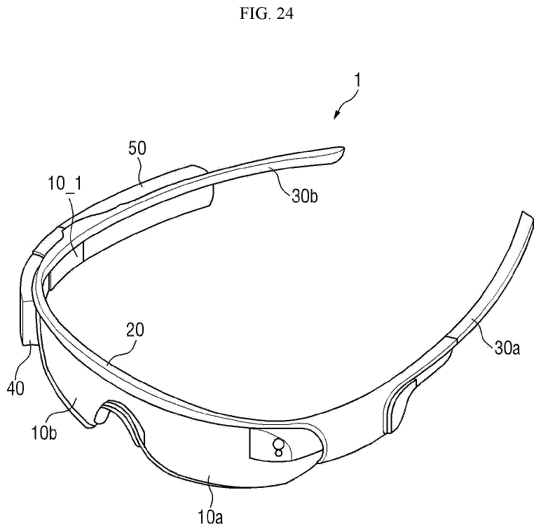

FIG. 23 is a diagram illustrating a vehicle instrument panel and a center fascia including a display device according to one or more embodiments.

Referring to FIG. 23, the micro display substrates 101 or the display panel included in the display device of the present disclosure may be applied as the display device 10 or the display device of a vehicle dashboard. For example, the display devices 10 to which the light emitting elements LE such as micro LEDs or the like are applied may be applied to a dashboard 10_a of a vehicle, a center fascia 10_b of a vehicle, or a center information display (CID) 10_c disposed at the dashboard of a vehicle. Further, the display device 10 according to one or more embodiments may be applied to room mirror displays 10_d and 10_e used instead of a side mirror of a vehicle, a navigation device, or the like.

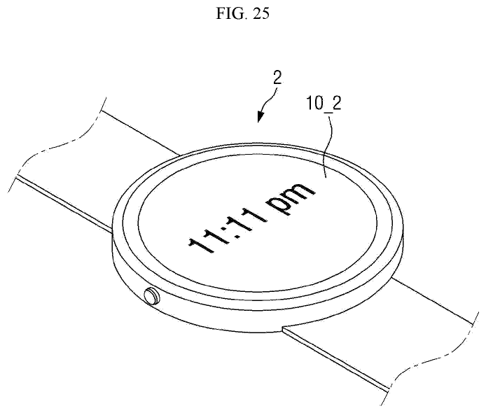

FIG. 24 is a diagram illustrating a glasses type virtual reality device including a display device according to one or more embodiments. FIG. 25 is a diagram illustrating a watch type smart device including a display device according to one or more embodiments.

FIG. 24 illustrates the glasses type virtual reality device 1 including temples 30a and 30b. The glasses type virtual reality device 1 according to one or more embodiments may include a virtual image display device 10_1, a left lens 10a, a right lens 10b, a support frame 20, the temples 30a and 30b, a reflection member 40, and a display device storage 50. The virtual image display device 10_1 may display a virtual image using the micro display substrates 101 illustrated in one or more embodiments of the present disclosure.

The glasses type virtual reality device 1 according to one or more embodiments may be applied to a head mounted display including a head mounted band that may be worn on a head, instead of the temples 30a and 30b. That is, the glasses type virtual reality device 1 according to one or more embodiments are not limited to that shown in FIG. 24, and may be applied in various forms to various electronic devices.

Further, as illustrated in FIG. 25, the micro display substrates 101 illustrated in one or more embodiments of the present disclosure may be applied as a position display device 10_2 of a watch-type smart device 2 that is one of the smart devices.

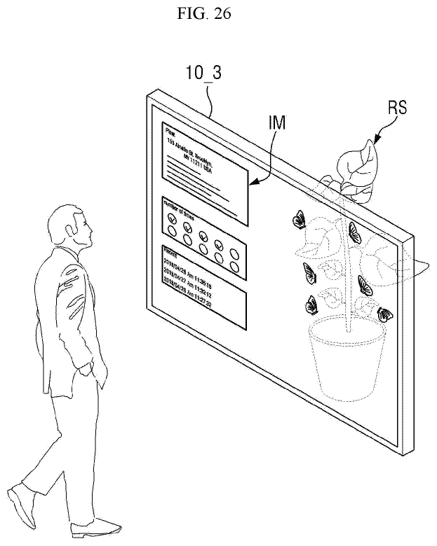

FIG. 26 is a diagram illustrating a transparent display device including a display device according to one or more embodiments.

Referring to FIG. 26, the main micro display substrates 101 illustrated in one or more embodiments of the present disclosure may be applied to a transparent display device. The transparent display device may display an image IM, and also may transmit light. Thus, a user located on the front side of the transparent display device can view an object RS or a background on the rear side of the transparent display device as well as the image IM displayed on the micro display panel. When the micro display substrate 101 is applied to the transparent display device, the micro display substrate 101 shown in FIG. 26 may include a light transmitting portion capable of transmitting light or may be made of a material capable of transmitting light.

In concluding the detailed description, those skilled in the art will appreciate that many variations and modifications can be made to the embodiments without substantially departing from the principles and scope of the present disclosure. Therefore, the disclosed embodiments of the present disclosure are used in a generic and descriptive sense only and not for purposes of limitation.

What is claimed is:

1. An apparatus for fabricating a display panel, comprising:
a film fixing module configured to fix a stretched film on which a plurality of light emitting elements are arranged;
a film pressurizing module configured to pressurize the stretched film;
a first thickness detection module configured to detect, at each pressurization step, a modulus of elasticity and a change in thickness of the stretched film that is pressurized and stretched by the film pressurizing module;
a second thickness detection module configured to detect, at each pressurization step, a change in thickness of an adhesive applied in a front direction of the stretched film;
an image detection module configured to photograph the plurality of light emitting elements arranged on the stretched film for each pressurization step and to detect a change in arrangement information of the light emitting elements; and
a main processor configured to database feature change information of at least one of the thickness of the stretched film, the modulus of elasticity, the thickness of the adhesive, or the arrangement information of the light emitting elements according to a change in pressing force for each pressurization step.

2. The apparatus of claim 1, wherein the film pressurizing module pressurizes one surface of the stretched film by gradually increasing the pressing force for each pressurization step in n steps, where n is a positive integer.

3. The apparatus of claim 1, wherein the first thickness detection module is located in a stretching direction in which the stretched film is stretched or in one lateral direction in which the stretched film is stretched to detect, at each pressurization step, a change in the thickness of the stretched film and a modulus of elasticity that varies depending on the change in the thickness of the stretched film, and
wherein the first thickness detection module is configured to transmit elastic modulus detection data and first thickness detection data according to the change in the thickness of the stretched film to the main processor.

4. The apparatus of claim 3, wherein the second thickness detection module is configured to:
detect a light quantity detection signal corresponding to a change in the adhesive thickness of the stretched film by using at least one light receiving element, a light emitting element, and a sensor under control of a microprocessor; and
convert the light quantity detection signal to a digital data signal to transmit second thickness detection data corresponding to the change in the adhesive thickness in the front direction of the stretched film to the main processor.

5. The apparatus of claim 4, wherein the image detection module is configured to:
analyze arrangement images of the light emitting elements for each pressurization step of the stretched film to detect damage rate data, transfer rate data and density change information of the light emitting elements for each pressurization step of the stretched film; and
transmit the damage rate data, the transfer rate data, and the density change information of the light emitting elements to the main processor.

6. The apparatus of claim 5, wherein the main processor is configured to:
receive pressing force magnitude information for each pressurization step from the film pressurizing module; and
based on the pressing force magnitude information for each step of the film pressurizing module, sort and database specifications comprising at least one feature selected from the group of type, model name, or area of the stretched film, the first thickness detection data, the elastic modulus detection data, the second thickness detection data, the damage rate data of the light emitting elements, the transfer rate data, and the density change information of the light emitting elements.

7. The apparatus of claim 6, wherein the main processor is configured to match and compare layout shape data comprising a pixel size, pixel shape, and pixel arrangement structure of a display substrate for each display panel set in advance with the arrangement images of the light emitting elements, and to generate and output a simulation result image in which the light emitting elements of the stretched film are transferred to the pixel shapes of the display substrate.

8. The apparatus of claim 6, wherein the main processor is configured to match the transfer rate data and the density change information of the light emitting elements for each pressurization step compared to layout shape data comprising a pixel size, pixel shape, and pixel arrangement structure of a display substrate for each display panel set in advance, and to output, as a simulation result, a layout drawing obtained by matching the layout shape data of the display substrate with the transfer rate data and the density change information of the light emitting elements.

9. The apparatus of claim 5, wherein the main processor comprises:
an elastic modulus detection unit configured to extract a thickness change value and an elastic modulus value according to the change in the thickness of the stretched film that is pressurized and stretched for each step by the film pressurizing module through the first thickness detection data from the first thickness detection module;
an image analysis unit configured to analyze the arrangement images of the light emitting elements inputted from the image detection module to detect each of the damage rate data and the transfer rate data of the light emitting elements for each pressurization step of the stretched film;
a density detection unit configured to analyze the arrangement images of the light emitting elements to detect the density change information of the light emitting elements for each pressurization step;
a data analysis processing unit configured to sort and database specifications comprising type, model name, and area information of the stretched film, the first thickness detection data, the elastic modulus detection data, and the second thickness detection data based on pressing force magnitude information for each step of the film pressurizing module; and
a result output unit configured to output at least one of the databased specification to a separate server or monitor.

10. The apparatus of claim 9, wherein based on the pressing force magnitude information for each step of the film pressurizing module, the data analysis processing unit is configured to sort and database specifications comprising at least one feature selected from the group of type, model name, or area of the stretched film, the first thickness detection data, the elastic modulus detection data, the second thickness detection data, the damage rate data of the light emitting elements, the transfer rate data, and the density change information of the light emitting elements.

11. The apparatus of claim 9, wherein the main processor further comprises a simulation processing unit configured to match and compare layout shape data comprising a pixel size, pixel shape, and pixel arrangement structure of a display substrate for each display panel set in advance with the arrangement images of the light emitting elements, and generate a simulation result image in which the light emitting elements of the stretched film are transferred to the pixel shapes of the display substrate.

12. The apparatus of claim 9, wherein the main processor further comprises a simulation processing unit configured to match the transfer rate data and the density change information of the light emitting elements for each pressurization step compared to layout shape data comprising a pixel size, pixel shape, and pixel arrangement structure of a display substrate for each display panel set in advance, and output, as a simulation result, a layout drawing obtained by matching the layout shape data of the display substrate with the transfer rate data and the density change information of the light emitting elements.

13. A fabricating method of a display panel, comprising:
fixing a stretched film on which a plurality of light emitting elements are arranged to a film fixing module;
pressurizing, by a film pressurizing module, the stretched film;
detecting, by a first thickness detection module, at each pressurization step, a modulus of elasticity and a change in thickness of the stretched film that is pressurized and stretched by the film pressurizing module;
detecting, by a second thickness detection module, at each pressurization step, a change in thickness of an adhesive applied in a front direction of the stretched film;
photographing, by an image detection module, the plurality of light emitting elements arranged on the stretched film for each pressurization step and detecting a change in arrangement information of the light emitting elements; and
databasing, by a main processor, feature change information of at least one of the thickness of the stretched film, the modulus of elasticity, the thickness of the adhesive, or the arrangement information of the light emitting elements according to a change in pressing force for each pressurization step.

14. The fabricating method of claim 13, wherein the pressurizing of the stretched film comprises pressurizing, by the film pressurizing module, one surface of the stretched film by gradually increasing the pressing force for each pressurization step in n steps, where n is a positive integer.

15. The fabricating method of claim 13, wherein the detecting of the modulus of elasticity of the stretched film at each pressurization step comprises:
detecting, at each pressurization step, a change in the thickness of the stretched film and a modulus of elasticity that varies depending on the change in the thickness; and
transmitting elastic modulus detection data and first thickness detection data according to the change in the thickness of the stretched film to the main processor.

16. The fabricating method of claim 13, wherein the detecting of a change in the adhesive thickness comprises:
detecting a light quantity detection signal corresponding to the change in the adhesive thickness of the stretched film by using at least one light receiving element, a light emitting element, and a sensor under control of a microprocessor, and
converting the light quantity detection signal into a digital data signal to transmit second thickness detection data corresponding to the change in the adhesive thickness in the front direction of the stretched film to the main processor.

17. The fabricating method of claim 16, wherein the detecting of the change in arrangement information of the light emitting elements comprises:
analyzing arrangement images of the light emitting elements for each pressurization step of the stretched film to detect damage rate data, transfer rate data and density change information of the light emitting elements for each pressurization step of the stretched film, and
transmitting the damage rate data, the transfer rate data, and the density change information of the light emitting elements to the main processor.

18. The fabricating method of claim 16, wherein the databasing of the feature change information of the light emitting elements comprises:
receiving pressing force magnitude information for each pressurization step from the film pressurizing module, and
based on the pressing force magnitude information for each step of the film pressurizing module, sorting specifications comprising at least one feature selected from the group of type, model name, or area of the stretched film, first thickness detection data, elastic modulus detection data, the second thickness detection data, damage rate data of the light emitting elements, transfer rate data, and density change information of the light emitting elements.

19. The fabricating method of claim 18, wherein the databasing of the feature change information of the light emitting elements further comprises:
matching and comparing layout shape data comprising a pixel size, pixel shape, and pixel arrangement structure of a display substrate for each display panel set in advance with arrangement images of the light emitting elements; and
generating and outputting a simulation result image in which the light emitting elements of the stretched film are transferred to the pixel shapes of the display substrate.

20. The fabricating method of claim 18, wherein the databasing of the feature change information of the light emitting elements further comprises:
matching the transfer rate data and the density change information of the light emitting elements for each pressurization step compared to layout shape data comprising a pixel size, pixel shape, and pixel arrangement structure of a display substrate for each display panel set in advance; and
outputting, as a simulation result, a layout drawing obtained by matching the layout shape data of the display substrate with the transfer rate data and the density change information of the light emitting elements.
